(19) United States
(12) Patent Application Publication
(10) Pub. No.: US 2026/0152687 A1
(43) Pub. Date: Jun. 4, 2026

(54) COMPOSITION, METHOD OF TREATING METAL-CONTAINING LAYER, AND METHOD OF MANUFACTURING SEMICONDUCTOR DEVICE

(71) Applicant: Samsung Electronics Co., Ltd., Suwon-si (KR)

(72) Inventors: Jina KIM, Suwon-si (KR); Giho KO, Suwon-si (KR); Sungmin KIM, Suwon-si (KR); Youngchan KIM, Suwon-si (KR); Juhee MOON, Suwon-si (KR); Jinhye BAE, Suwon-si (KR); Wonsik YOON, Suwon-si (KR); Minhyung CHO, Suwon-si (KR); Cheol HAM, Suwon-si (KR); Kyuyoung HWANG, Suwon-si (KR)

(73) Assignee: Samsung Electronics Co., Ltd., Suwon-si (KR)

(21) Appl. No.: 19/404,381

(22) Filed: Dec. 1, 2025

(30) Foreign Application Priority Data
Dec. 3, 2024 (KR) 10-2024-0177899
Aug. 5, 2025 (KR) 10-2025-0107689

(51) Int. Cl. C09K 13/00; H10D 30/01

(52) U.S. Cl. CPC C09K 13/00; H10D 30/024

(57) ABSTRACT

Provided are a composition, a method of treating a metal-containing layer by using the composition, and a method of manufacturing a semiconductor device by using the composition. The composition may include an oxidizing agent, an ammonium-containing compound, and an etching controller. The etching controller may include a compound represented by Formula 1. A description of Formula 1 is provided herein.

### CROSS-REFERENCE TO RELATED APPLICATION

This application is based on and claims priority under 35 U.S.C. § 119 to Korean Patent Applications Nos. 10-2024-0177899, filed on Dec. 3, 2024, and 10-2025-0107689, filed on Aug. 5, 2025, in the Korean Intellectual Property Office, the disclosure of which is incorporated by reference herein in its entirety.

### BACKGROUND

### 1. Field

The disclosure relates to a composition, a method of treating a metal-containing layer by using the composition, and/or a method of manufacturing a semiconductor device by using the composition.

### 2. Description of the Related Art

To meet the superior performance and low price demands of consumers, increased integration and improved reliability of electronic devices, for example semiconductor devices, may be required. As the integration of semiconductor devices increases, damage to the components of semiconductor devices during manufacturing processes of the semiconductor devices may have a greater impact on the reliability and/or electrical characteristics of semiconductor devices. In particular, during the manufacturing processes of semiconductor devices, various treatment processes, such as etching and cleaning processes, may be performed on a given layer (for example, a metal-containing layer). There may be a continuous demand for a composition having an appropriate etching rate and/or an excellent cleaning ability for performing an effective metal-containing layer treatment process.

### SUMMARY

Provided are a composition having improved and/or excellent etching rate control performance, improved and/or excellent cleaning performance, and improved and/or excellent process stability, a method of treating a metal-containing layer using the composition, and/or a method of manufacturing a semiconductor device using the composition.

Additional aspects will be set forth in part in the description which follows and, in part, will be apparent from the description, or may be learned by practice of the presented embodiments of the disclosure.

According to an example embodiment of the disclosure, a composition may include an oxidizing agent, an ammonium-containing compound, and an etching controller. The etching controller may include a compound represented by Formula 1.

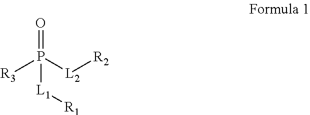

In Formula 1,
L₁ and L₂ may each independently be a single bond or oxygen,
R₁ may be hydrogen, a C₁-C₅₀ alkyl group, or a C₂-C₅₀ alkenyl group,
R₂ and R₃ may each independently be a C₁-C₅₀ alkyl group or a C₂-C₅₀ alkenyl group, and
in R₂, R₃, and R₁ when R₁ is not hydrogen, at least one hydrogen in each of the C₁-C₅₀ alkyl group and the C₂-C₅₀ alkenyl group may optionally be substituted with a halogen atom.

In some embodiments, the oxidizing agent may include hydrogen peroxide.

In some embodiments, the ammonium-containing compound may include dihydrogen phosphate ([H₂PO₄]⁻), hydrogen phosphate ([HPO₄]²⁻), or phosphate ([PO₄]³⁻).

In some embodiments, in Formula 1, i) L₁ may be oxygen and L₂ may be a single bond, or ii) L₁ and L₂ may each be oxygen.

In some embodiments, in Formula 1, R₁ may be hydrogen or a C₁-C₅ alkyl group.

In some embodiments, in Formula 1, R₂ and R₃ may each independently be a branched C₃-C₅₀ alkyl group.

In some embodiments, the etching controller may further include an azole-containing compound and the azole-containing compound may include a pyrazole group, an imidazole group, a triazole group, or tetrazole group.

In some embodiments, a weight ratio of the compound represented by Formula 1 and the azole-containing compound may be selected from a range of 99:1 to 50:50.

According to an example embodiment of the disclosure, a method of treating a metal-containing layer may include:
preparing a metal-containing layer including a first region and a second region, wherein a material in the first region of the metal-containing layer may be different from a material in the second region of the metal-containing layer; and
contacting the metal-containing layer with a composition.

The first region of the metal-containing layer and the second region of the metal-containing layer may each independently include titanium (Ti), indium (In), aluminum (Al), lanthanum (La), scandium (Sc), gallium (Ga), copper (Cu), cobalt (Co), tungsten (W), ruthenium (Ru), molybdenum (Mo), zinc (Zn), hafnium (Hf), or any combination thereof.

The composition may include an oxidizing agent, an ammonium-containing compound, and an etching controller.

The etching controller comprises the compound represented by Formula 1.

In some embodiments, the first region of the metal-containing layer may include copper (Cu), cobalt (Co), tungsten (W), ruthenium (Ru), or any combination thereof.

In some embodiments, the second region of the metal-containing layer may include titanium nitride, titanium oxynitride, or any combination thereof.

In some embodiments, a second etching rate at which the composition etches the second region may be greater than a first etching rate at which the composition etches the first region.

According to an example embodiment of the disclosure, a method of manufacturing a semiconductor device may include:
preparing a first insulating layer, a first conductive pattern in the first insulating layer, a second insulating layer on the first insulating layer, and an opening-forming mask pattern on the second insulating layer;
forming an opening in the second insulating layer by etching the second insulating layer using the opening-forming mask pattern;
contacting the opening-forming mask pattern and an exposed surface of the inside of the opening with a composition; and
providing a conductive material in the opening, the conductive material being configured to be electrically connected to the first conductive pattern, wherein
the composition may include an oxidizing agent, an ammonium-containing compound, and an etching controller, and
the etching controller may include the compound represented by Formula 1.

In some embodiments, the first conductive pattern may include copper (Cu), cobalt (Co), tungsten (W), ruthenium (Ru), or any combination thereof.

In some embodiments, the opening-forming mask pattern may include titanium (Ti), indium (In), aluminum (Al), lanthanum (La), scandium (Sc), gallium (Ga), or any combination thereof.

In some embodiments, the opening-forming mask pattern may include a metal nitride, a metal oxynitride, or any combination thereof.

In some embodiments, the opening-forming mask pattern may include titanium nitride, titanium oxynitride, or any combination thereof. Each of the titanium nitride and the titanium oxynitride optionally further comprises indium (In), aluminum (Al), lanthanum (La), scandium (Sc), gallium (Ga), silicon (Si), or any combination thereof.

In some embodiments, the first conductive pattern may include a first barrier layer pattern and a first filling layer on the first barrier layer pattern.

In some embodiments, in the forming of the opening, a surface residue may be formed on at least one of a surface of the opening-forming mask pattern and the exposed surface of the inside of the opening, and the opening-forming mask pattern and the surface residue may be removed by the contacting the opening-forming mask pattern and the exposed surface of the inside of the opening with the composition.

### BRIEF DESCRIPTION OF THE DRAWINGS

The above and other aspects, features, and advantages of certain embodiments of the disclosure will be more apparent from the following description taken in conjunction with the accompanying drawings, in which:

FIGS. 1, 2A and 2B are drawings briefly illustrating an embodiment of a method of treating a metal-containing layer;

FIG. 3 is a process flow diagram of an embodiment of a method of manufacturing an electronic device;

FIGS. 4A to 4J are cross-sectional views illustrating an embodiment of a process of forming a trench and via hole pattern to form a bitline electrode;

FIG. 5 is a photograph, in which A indicates a composition of Example 1, and B indicates a composition of Comparative Example C1;

FIG. 6A is a scanning electron microscope (SEM) photograph of the inside of an opening observed after performing a rinsing and drying process using the composition of Example 1;

FIG. 6B is a SEM photograph of the inside of an opening observed after performing a rinsing and drying process using a composition of Comparative Example C2;

FIGS. 7A to 7E are schematic views for describing a method of manufacturing a semiconductor device according to an embodiment; and

FIGS. 8 to 11 are schematic views for describing a semiconductor device according to another embodiment, respectively.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects. As used herein, the singular forms “a,” “an” and “the” are intended to include the plural forms as well, unless the context clearly indicates otherwise.

As used herein, the term “and/or” includes any and all combinations of one or more of the associated listed items. Expressions such as “at least one of,” when preceding a list of elements, modify the entire list of elements and do not modify the individual elements of the list. For example, “at least one of A, B, and C,” and similar language (e.g., “at least one selected from the group consisting of A, B, and C” and “at least one of A, B, or C”) may be construed as A only, B only, C only, or any combination of two or more of A, B, and C, such as, for instance, ABC, AB, BC, and AC.

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes. When ranges are specified, the range includes all values therebetween such as increments of 0.1%.

While the term “equal to” is used in the description of example embodiments, it should be understood that some imprecisions may exist. Thus, when one element is referred to as “equal to” another element, it should be understood that an element or a value may be “equal to” another element within a desired manufacturing or operational tolerance range (e.g., ±10%).

### Metal-Containing Layer

A metal included in the metal-containing layer may include an alkali metal (for example, sodium (Na), potassium (K), rubidium (Rb), cesium (Cs), etc.), an alkaline earth metal (for example, beryllium (Be), magnesium (Mg), calcium (Ca), strontium (Sr), barium (Ba), etc.), a lanthanide metal (for example, lanthanum (La), europium (Eu), terbium (Tb), ytterbium (Yb), etc.), a transition metal (for example, scandium (Sc), yttrium (Y), titanium (Ti), zirconium (Zr), hafnium (Hf), vanadium (V), niobium (Nb), tantalum (Ta), chromium (Cr), molybdenum (Mo), tungsten (W), manganese (Mn), iron (Fe), ruthenium (Ru), osmium (Os), cobalt (Co), rhodium (Rh), nickel (Ni), copper (Cu), silver (Ag), zinc (Zn), etc.), a post-transition metal (for example, aluminum (AI), gallium (Ga), indium (In), thallium (TI), tin (Sn), or bismuth (Bi), etc.), or any combination thereof.

According to an embodiment, the metal included in the metal-containing layer may include Ti, In, Al, La, Sc, Ga, Cu, Co, W, Ru, Mo, Zn, Hf, or any combination thereof.

According to another embodiment, the metal-containing layer may include two or more different metals.

According to another embodiment, the metal-containing layer may include metal, a metal nitride, a metal oxide, a metal oxynitride, or any combination thereof.

According to another embodiment, the metal-containing layer may include titanium.

According to another embodiment, the metal-containing layer includes i) titanium (Ti), and may optionally further include ii) indium (In), aluminum (Al), lanthanum (La), scandium (Sc), gallium (Ga), tungsten (W), molybdenum (Mo), ruthenium (Ru), zinc (Zn), hafnium (Hf), silicon (Si), or any combination thereof, in addition to titanium (Ti). For example, the metal-containing layer may include titanium nitride, titanium nitride further including aluminum (e.g., TiAlN), titanium nitride further including lanthanum, titanium nitride further including silicon (e.g., TiSiN), or the like.

According to another embodiment, the metal-containing layer may include a conductive metal (e.g., copper, cobalt, tungsten, ruthenium, and the like).

According to another embodiment, the metal-containing layer may include i) a metal nitride, a metal oxynitride, or any combination thereof (e.g., titanium nitride, titanium oxynitride, or any combination thereof) and ii) a conductive metal (e.g., copper, cobalt, tungsten, ruthenium, and the like).

The metal-containing layer may be a single-layered structure including one or more materials, or a multi-layered structure including different materials. The plurality of layers included in the multi-layered structure may be vertically stacked or horizontally arranged with respect to the substrate. The single-layered structure and multi-layered structure may have various three-dimensional patterns (for example, via holes, trenches, etc.).

Meanwhile, the metal-containing layer may include a first region and a second region, and the first region and the second region may each independently include titanium (Ti), indium (In), aluminum (Al), lanthanum (La), scandium (Sc), gallium (Ga), copper (Cu), cobalt (Co), tungsten (W), ruthenium (Ru), molybdenum (Mo), zinc (Zn), hafnium (Hf), or any combination thereof, wherein a material included in the first region may be different from a material included in the second region.

According to an embodiment, the first region may include copper (Cu), cobalt (Co), tungsten (W), ruthenium (Ru), or any combination thereof.

According to another embodiment, the second region may include titanium (Ti), indium (In), aluminum (Al), lanthanum (La), scandium (Sc), gallium (Ga), or any combination thereof.

According to another embodiment, the first region may include a conductive metal (e.g., copper, cobalt, tungsten, and ruthenium).

According to another embodiment, the second region may include a metal nitride, a metal oxynitride, or any combination thereof (e.g., titanium nitride, titanium oxynitride, or any combination thereof).

According to another embodiment, the second region may include titanium nitride, titanium oxynitride, or any combination thereof. Each of the titanium nitride and titanium oxynitride may optionally further include indium (In), aluminum (Al), lanthanum (La), scandium (Sc), gallium (Ga), silicon (Si), or any combination thereof.

According to another embodiment, the second region may include i) titanium nitride, ii) titanium oxynitride, iii) titanium nitride further including indium (In), aluminum (Al), lanthanum (La), scandium (Sc), gallium (Ga), silicon (Si), or any combination thereof, iv) titanium oxynitride further including indium (In), aluminum (Al), lanthanum (La), scandium (Sc), gallium (Ga), silicon (Si), or any combination thereof, or v) any combination thereof.

### Composition

The composition may include an oxidizing agent, an ammonium-containing compound, and an etching controller.

The composition may be used in various treatment processes for the metal-containing layer described herein, such as etching, cleaning, and polishing processes.

The composition may further include water (e.g., deionized water).

According to an embodiment, the composition may not include a polishing agent.

According to another embodiment, the composition may not include fluorine (F).

According to another embodiment, the composition may further include a pH regulator. For example, the pH regulator may be ammonium hydroxide, tetramethylammonium hydroxide (TMAH), or the like, but is not limited thereto.

Throughout the specification, the expression “etching a layer” may refer to removing at least a portion of a material constituting the layer.

### Oxidizing Agent

The oxidizing agent serves to etch at least a portion of the metal-containing layer by oxidizing at least a portion of the metal (e.g., titanium) in the metal-containing layer to form a water-soluble complex, and may include, for example, at least one of hydrogen peroxide, nitric acid, and ammonium sulfate.

According to an embodiment, the oxidizing agent may include hydrogen peroxide.

According to another embodiment, the oxidizing agent may be hydrogen peroxide.

An amount (weight) of the oxidizing agent may be, for example, with respect to 100 wt % of the composition, about 1 wt % to about 50 wt %, about 10 wt % to about 50 wt %, about 16 wt % to about 50 wt %, about 18 wt % to about 50 wt %, about 20 wt % to about 50 wt %, about 22 wt % to about 50 wt %, about 25 wt % to about 50 wt %, about 1 wt % to about 45 wt %, about 10 wt % to about 45 wt %, about 16 wt % to about 45 wt %, about 18 wt % to about 45 wt %, about 20 wt % to about 45 wt %, about 22 wt % to about 45 wt %, about 25 wt % to about 45 wt %, about 1 wt % to about 40 wt %, about 10 wt % to about 40 wt %, about 16 wt % to about 40 wt %, about 18 wt % to about 40 wt %, about 20 wt % to about 40 wt %, about 22 wt % to about 40 wt %, about 25 wt % to about 40 wt %, about 1 wt % to about 35 wt %, about 10 wt % to about 35 wt %, about 16 wt % to about 35 wt %, about 18 wt % to about 35 wt %, about 20 wt % to about 35 wt %, about 22 wt % to about 35 wt %, about 25 wt % to about 35 wt %, about 1 wt % to about 30 wt %, about 10 wt % to about 30 wt %, about 16 wt % to about 30 wt %, about 18 wt % to about 30 wt %, about 20 wt % to about 30 wt %, about 22 wt % to about 30 wt %, about 25 wt % to about 30 wt %, about 16 wt % to about 27 wt %, about 18 wt % to about 27 wt %, about 20 wt % to about 27 wt %, about 22 wt % to about 27 wt %, or about 25 wt % to about 27 wt %.

When the amount of the oxidizing agent is within these ranges, the composition may have both improved and/or excellent etching selectivity and improved and/or excellent cleaning performance.

### Ammonium-Containing Compound

The ammonium-containing compound may serve to maintain a high concentration of anions generated from the oxidizing agent and to stabilize a water-soluble complex generated when the anions oxidize at least a portion of the metal (e.g., titanium) in the metal-containing layer. By using such an ammonium-containing compound, at least a portion of the metal-containing layer may be more effectively etched.

The ammonium-containing compound may include an ammonium group.

According to an embodiment, the ammonium-containing compound may include an ammonium group represented by N(A₁₁)(A₁₂)(A₁₃)(A₁₄), wherein A₁₁ to A₁₄ may each independently be hydrogen, a C₁-C₃₀ alkyl group, a C₂-C₃₀ alkenyl group, a C₃-C₃₀ carbocyclic group, or a C₁-C₃₀ heterocyclic group.

For example, A₁₁ to A₁₄ may each independently be hydrogen or a C₁-C₁₀ alkyl group.

According to another embodiment, the ammonium-containing compound may not include fluorine (F). Without being limited by any particular theory, when the ammonium-containing compound does not include fluorine, accelerated corrosion of the surface of the metal-containing layer may be substantially limited and/or prevented, and the metal-containing layer treatment process using the composition may be performed in a safe and environmentally friendly atmosphere.

According to another embodiment, the ammonium-containing compound may include hydroxide, acetate, bicarbonate, benzoate, carbonate, formate, nitrate, hydrogen sulfate, carbamate, sulfamate, citrate, phosphate, sulfite, sulfobenzoate, oxalate, lactate, tartrate, dihydrogen citrate, glutamate, salicylate, bioxalate, octanoate, propionate, glycolate, or gluconate.

According to another embodiment, the ammonium-containing compound may include phosphate or hydroxide.

According to another embodiment, the ammonium-containing compound may include dihydrogen phosphate ([H₂PO₄]⁻), hydrogen phosphate ([HPO₄]²⁻), or phosphate ([PO₄]³⁻).

According to another embodiment, the ammonium-containing compound may include a compound represented by Formula 11-1, a compound represented by Formula 11-2, a compound represented by Formula 11-3, or any combination thereof:

$${[ N ( {A}_{11} ) ( {A}_{12} ) ( {A}_{13} ) ( {A}_{14} ) ]}_{3} {PO}_{4} \qquad Formula 11 - 1$$

$${[ N ( {A}_{11} ) ( {A}_{12} ) ( {A}_{13} ) ( {A}_{14} ) ]}_{2} {HPO}_{4} \qquad Formula 11 - 2$$

$$[ N ( {A}_{11} ) ( {A}_{12} ) ( {A}_{13} ) ( {A}_{14} ) ] {H}_{2} {PO}_{4} \qquad Formula 11 - 3$$

wherein, in Formulae 11-1 to 11-3, A₁₁ to A₁₄ may each be the same as described herein.

According to another embodiment, the ammonium-containing compound may include at least one of ammonium phosphate ((NH₄)₃PO₄), diammonium monohydrogen phosphate ((NH₄)₂HPO₄), ammonium dihydrogen phosphate ((NH₄)H₂PO₄), [N(CH₃)₄]₃PO₄, bis(tetramethylammonium) monohydrogen phosphate ([N(CH₃)₄]₂HPO₄), and tetramethylammonium dihydrogen phosphate ([N(CH₃)₄]H₂PO₄).

An amount (weight) of the ammonium-containing compound may be, for example, with respect to 100 wt % of the composition, about 0.01 wt % to about 10 wt %, about 0.05 wt % to about 10 wt %, about 0.1 wt % to about 10 wt %, about 0.3 wt % to about 10 wt %, about 0.5 wt % to about 10 wt %, about 0.01 wt % to about 7 wt %, about 0.05 wt % to about 7 wt %, about 0.1 wt % to about 7 wt %, about 0.3 wt % to about 7 wt %, about 0.5 wt % to about 7 wt %, about 0.01 wt % to about 4 wt %, about 0.05 wt % to about 4 wt %, about 0.1 wt % to about 4 wt %, about 0.3 wt % to about 4 wt %, about 0.5 wt % to about 4 wt %, about 0.01 wt % to about 2 wt %, about 0.05 wt % to about 2 wt %, about 0.1 wt % to about 2 wt %, about 0.3 wt % to about 2 wt %, about 0.5 wt % to about 2 wt %, about 0.01 wt % to about 1 wt %, about 0.05 wt % to about 1 wt %, about 0.1 wt % to about 1 wt %, about 0.3 wt % to about 1 wt %, about 0.5 wt % to about 1 wt %, about 0.01 wt % to about 0.7 wt %, about 0.05 wt % to about 0.7 wt %, about 0.1 wt % to about 0.7 wt %, about 0.3 wt % to about 0.7 wt %, about 0.5 wt % to about 0.7 wt %, about 0.01 wt % to about 0.5 wt %, about 0.05 wt % to about 0.5 wt %, about 0.1 wt % to about 0.5 wt %, or about 0.3 wt % to about 0.5 wt %.

When the amount of the ammonium-containing compound is within these ranges, the composition may have both improved and/or excellent etching selectivity and improved and/or excellent cleaning performance.

### Etching Controller

The etching controller may serve to control the etching rate (e.g., suppress etching) and the like by interacting with various metal (e.g., copper, cobalt, tungsten, ruthenium, and the like) atoms in the metal-containing layer, which is a layer to be treated. In addition, the etching controller may serve to remove various surface residues generated during a deposition process and/or a patterning process of the metal-containing layer.

The etching controller may include a compound represented by Formula 1:

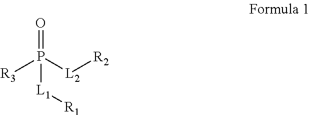

wherein, in Formula 1,
L₁ and L₂ may each independently be a single bond or oxygen,
R₁ may be hydrogen, a C₁-C₅₀ alkyl group, or a C₂-C₅₀ alkenyl group,
R₂ and R₃ may each independently be a C₁-C₅₀ alkyl group or a C₂-C₅₀ alkenyl group, and
in R₂, R₃, and R₁ when R₁ is not hydrogen, at least one hydrogen in each of the C₁-C₅₀ alkyl group and the C₂-C₅₀ alkenyl group may optionally be substituted with a halogen atom.

Each of the C₁-C₅₀ alkyl group and the C₂-C₅₀ alkenyl group may be linear or branched.

According to an embodiment, at least one of L₁ and L₂ of Formula 1 may be oxygen. Accordingly, the compound represented by Formula 1 and various metal (e.g., copper, cobalt, tungsten, ruthenium, and the like) atoms in the metal-containing layer may be effectively coordinated and bonded to each other, so that a protective layer including the compound represented by Formula 1 may be appropriately formed on the surface of the metal-containing layer. For example, in Formula 1, i) L₁ may be oxygen and L₂ may be a single bond, or ii) L₁ and L₂ may each be oxygen.

According to another embodiment, in Formula 1, R₁ may be hydrogen or a C₁-C₂₀ alkyl group. For example, in Formula 1, R₁ may be hydrogen or a C₁-C₁₀ alkyl group. As another example, in Formula 1, R₁ may be hydrogen or a C₁-C₅ alkyl group (for example, methyl, etc.).

According to another embodiment, in Formula 1, R₂ and R₃ may each independently be a C₁-C₂₀ alkyl group or a C₂-C₂₀ alkenyl group. For example, in Formula 1, R₂ and R₃ may each independently be a C₅-C₂₀ alkyl group or a C₅-C₂₀ alkenyl group.

According to another embodiment, in Formula 1, R₂ and R₃ may each be a C₅-C₂₀ alkyl group, a C₅-C₁₀ alkyl group, a C₆-C₉ alkyl group, or a C₇-C₈ alkyl group.

According to another embodiment, in Formula 1, at least one of R₂ and R₃ (for example, R₂ and R₃) may each independently be a branched C₃-C₅₀ alkyl group, a branched C₃-C₂₀ alkyl group, a branched C₅-C₂₀ alkyl group, a branched C₅-C₁₀ alkyl group, a branched C₆-C₉ alkyl group, or a branched C₇-C₈ alkyl group.

According to another embodiment, in Formula 1, R₂ and R₃ may be identical to each other.

According to another embodiment, in Formula 1, R₂ and R₃ may be different from each other.

According to another embodiment, the etching controller may include a compound represented by Formula 1(1), a compound represented by Formula 1(2), or any combination thereof:

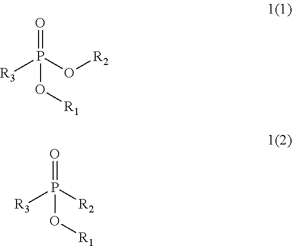

wherein, in Formulae 1(1) and 1(2), R₁ to R₃ may each be the same as described herein.

According to another embodiment, the etching controller may include at least one of Compounds 1 and 2:

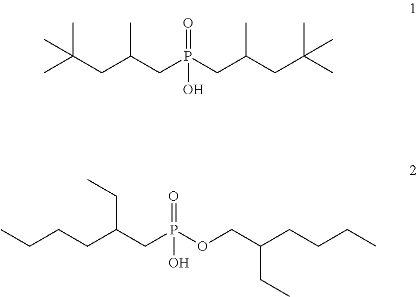

In Formula 1, R₂ and R₃ may each independently be a C₁-C₅₀ alkyl group or a C₂-C₅₀ alkenyl group. In addition, in Formula 1, hydrogens in each of the C₁-C₅₀ alkyl group and the C₂-C₅₀ alkenyl group, which may be R₁ to R₃, may be unsubstituted, or at least one hydrogen in each of the C₁-C₅₀ alkyl group and the C₂-C₅₀ alkenyl group, which may be R₁ to R₃, may be substituted with a halogen atom. Thus, for example, each of the C₁-C₅₀ alkyl group and the C₂-C₅₀ alkenyl group, which may be R₁ to R₃, may not include an alkoxy group, an alkylthio group, a phosphoric acid group, an amine derivative group, and the like as a substituent. Since a) R₃ as defined above is a hydrophobic group and b) a group represented by *-L₂-R₂, wherein L₂ is a single bond, is a hydrophobic group, a compound represented by Formula 1 may provide an appropriate hydrophobic protective layer to the surface of the metal-containing layer, which is a layer to be treated. In addition, by R₂ and R₃ as defined above, additional reactions between the hydrophobic protective layer and the metal ions surrounding it may be substantially limited and/or suppressed, so that the hydrophobic protective layer may be more easily removed together with various surface residues to be removed later. Therefore, during bringing the metal-containing layer into contact with the composition, control of selective etching rate (e.g., suppress of etching) with respect to certain metal may be effectively performed, and simultaneously, residues (the surface residue and/or an etching controller-derived residue) may not substantially remain on the surface of the metal-containing layer. Descriptions for the terms of the “surface residue” and the “etching controller-derived residue” may each be the same as described herein.

Furthermore, the compound represented by Formula 1 having R₂ and R₃ as defined above may have a large steric hindrance and may be difficult to be aligned regularly, so that micelles may not be substantially formed. Therefore, when manufacturing the composition and/or when treating a metal-containing layer using the composition, bubbles may not be substantially formed. Since the bubbles may cause a decrease in the efficiency and stability of the metal-containing layer treatment process, wafer damage, residue regeneration, contamination of various equipment, and the like, it may be advantageous to limit and/or prevent bubble formation when manufacturing the composition and/or when treating the metal-containing layer by using the composition. Without being limited by any particular theory, a composition with which bubble formation is observed during and/or immediately after the manufacture thereof may be substantially unsuitable for use in the treatment of the metal-containing layer, as the bubbles may interfere with uniform contact between the composition and the metal-containing layer and may be the cause of additional residue formation on the surface of the metal-containing layer.

Therefore, by using the composition including the compound represented by Formula 1, the etching rate may be selectively controlled depending on the metal in the metal-containing layer without bubble formation, and at the same time, the residues may be more effectively removed.

According to another embodiment, the etching controller may further include an azole-containing compound, in addition to the compound represented by Formula 1.

An azole in the azole-containing compound may include two, three, or four nitrogens as a ring-forming atom.

According to another embodiment, the azole-containing compound may include a pyrazole group, an imidazole group, a triazole group, or a tetrazole group.

According to another embodiment, the azole-containing compound may include a pyrazole group.

According to another embodiment, the azole-containing compound may include a compound represented by Formula 2, a compound represented by Formula 3, a compound represented by Formula 4, a compound represented by Formula 5, a compound represented by Formula 6, a compound represented by Formula 7, a compound represented by Formula 8, a compound represented by Formula 9, or any combination thereof:

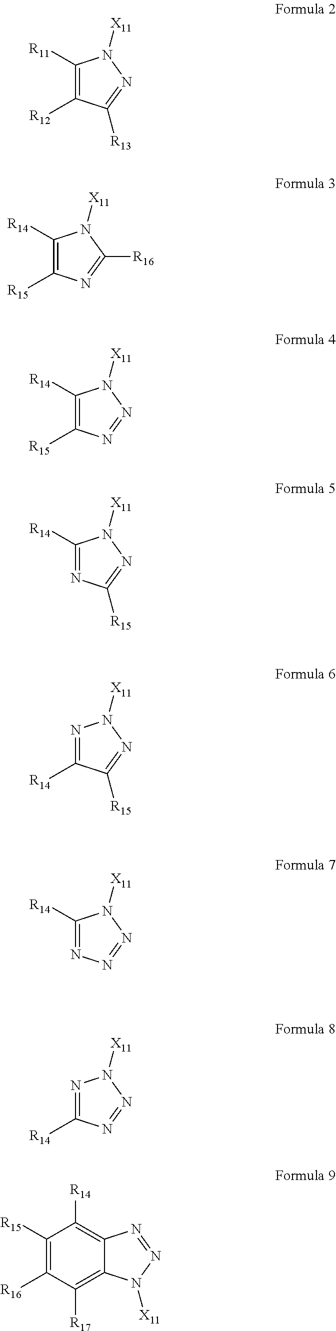

wherein, in Formulae 2 to 9,
X₁₁ may be hydrogen, a C₁-C₅₀ alkyl group, a C₂-C₅₀ alkenyl group, or a phenyl group,
R₁₁ to R₁₇ may each independently be hydrogen, halogen, a nitro group (—NO₂), a C₁-C₅₀ alkyl group, a C₂-C₅₀ alkenyl group, or a phenyl group, and
in R₁₁ to R₁₇, and X₁₁ when X₁₁ is not hydrogen, at least one hydrogen in each of the C₁-C₅₀ alkyl group, the C₂-C₅₀ alkenyl group, and the phenyl group may optionally be substituted with a halogen atom.

According to another embodiment, X₁₁ in Formulae 2 to 9 may be hydrogen.

According to another embodiment, R₁₁ to R₁₇ in Formulae 2 to 9 may each independently be hydrogen, halogen, a nitro group (—NO₂), a C₁-C₁₀ alkyl group, a C₂-C₁₀ alkenyl group, or a phenyl group.

According to another embodiment, R₁₁ to R₁₇ in Formulae 2 to 9 may each independently be hydrogen, a nitro group (—NO₂), or a C₁-C₄ alkyl group (for example, methyl, ethyl, propyl, isopropyl, n-butyl, sec-butyl, iso-butyl, tert-butyl, etc.).

According to another embodiment, at least one of R₁₁, R₁₂ and R₁₃ in Formula 2 may each independently be halogen, a nitro group (—NO₂), a C₁-C₅₀ alkyl group, a C₂-C₅₀ alkenyl group, or a phenyl group.

According to another embodiment, at least one of R₁₁, R₁₂ and R₁₃ in Formula 2 may each independently be a nitro group (—NO₂), a C₁-C₅₀ alkyl group, or a C₂-C₅₀ alkenyl group.

According to another embodiment, at least one of R₁₁, R₁₂ and R₁₃ in Formula 2 may each independently be halogen, a nitro group (—NO₂), a C₁-C₁₀ alkyl group, a C₂-C₁₀ alkenyl group, or a phenyl group.

According to another embodiment, at least one of R₁₁, R₁₂ and R₁₃ in Formula 2 may each independently be a nitro group (—NO₂), a C₁-C₁₀ alkyl group, or a C₂-C₁₀ alkenyl group.

According to another embodiment, at least one of R₁₁, R₁₂ and R₁₃ in Formula 2 may each independently be a nitro group (—NO₂), or a C₁-C₄ alkyl group (for example, methyl, ethyl, propyl, isopropyl, n-butyl, sec-butyl, iso-butyl, tert-butyl, etc.).

According to another embodiment, R₁₂ in Formula 2 may be halogen, a nitro group (—NO₂), a C₁-C₁₀ alkyl group, a C₂-C₁₀ alkenyl group, or a phenyl group.

According to another embodiment, R₁₂ in Formula 2 may be a nitro group (—NO₂), or a C₁-C₄ alkyl group.

According to another embodiment, R₁₂ in Formula 2 may be a nitro group (—NO₂), or a C₁-C₄ alkyl group and R₁₁ and R₁₃ in Formula 2 may each be hydrogen.

According to another embodiment, R₁₄ to R₁₇ in Formulae 3 to 9 may each be hydrogen.

According to another embodiment, the azole-containing compound may include the compound represented by Formula 2.

According to another embodiment, the azole-containing compound may include the compound represented by Formula 9.

According to another embodiment, the azole-containing compound may include at least one of Compound C5, C11, C12, C13, C14, C15 and C16:

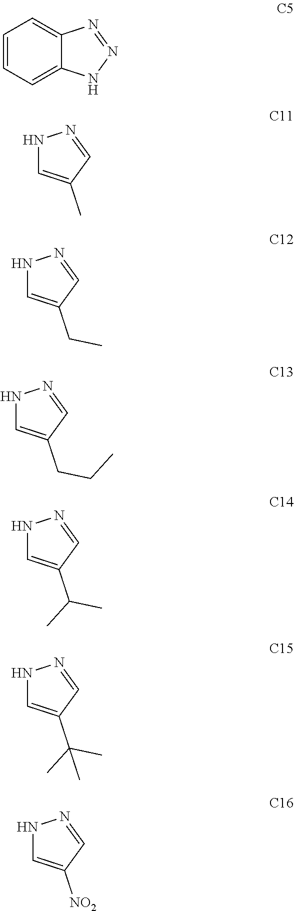

According to another embodiment, a weight ratio of the compound represented by Formula 1 and the azole-containing compound may be selected from a range of 99:1 to 50:50, 95:5 to 50:50, or 90:10 to 50:50. For example, the weight ratio of the compound represented by Formula 1 and the azole-containing compound may be 65:35, 90:10, or 50:50.

According to another embodiment, an amount (weight) of the azole-containing compound may be, with respect to 100 wt % of a total amounts of the compound represented by Formula 1 and the azole-containing compound, about 5 wt % to about 60 wt %, about 10 wt % to about 60 wt %, about 5 wt % to about 50 wt %, or about 10 wt % to about 50 wt %.

By using the azole-containing compound in addition to the compound represented by Formula 1 in the composition, the etching rate may be more selectively controlled depending on the metal in the metal-containing layer and at the same time, the residues may be more effectively removed.

An amount (weight) of the etching controller may be, with respect to 100 wt % of the composition, about 0.001 wt % to about 10 wt %, about 0.01 wt % to about 10 wt %, about 0.1 wt % to about 10 wt %, about 0.15 wt % to about 10 wt %, about 0.2 wt % to about 10 wt %, about 0.001 wt % to about 5 wt %, about 0.01 wt % to about 5 wt %, about 0.1 wt % to about 5 wt %, about 0.15 wt % to about 5 wt %, about 0.2 wt % to about 5 wt %, about 0.001 wt % to about 1 wt %, about 0.01 wt % to about 1 wt %, about 0.1 wt % to about 1 wt %, about 0.15 wt % to about 1 wt %, about 0.2 wt % to about 1 wt %, about 0.001 wt % to about 0.5 wt %, about 0.01 wt % to about 0.5 wt %, about 0.1 wt % to about 0.5 wt %, about 0.15 wt % to about 0.5 wt %, about 0.2 wt % to about 0.5 wt %, about 0.001 wt % to about 0.3 wt %, about 0.01 wt % to about 0.3 wt %, about 0.1 wt % to about 0.3 wt %, about 0.15 wt % to about 0.3 wt %, or about 0.2 wt % to about 0.3 wt %.

The composition as described above may have a pH range of about 1.0 to about 10.0, about 3.0 to about 10.0, about 5.0 to about 10.0, about 7.0 to about 10.0, about 3.0 to about 8.0, about 5.0 to about 8.0, or about 7.0 to about 8.0. When the pH of the composition is within these ranges, the interaction between the etching controller and the metal atoms in the metal-containing layer as described below may occur more easily.

According to an embodiment, the composition may be used in a metal-containing layer treatment process, for example, an etching process, a cleaning process, and the like for a metal-containing layer. The description of the metal-containing layer may be as described herein.

Alternatively, the composition may also be used as an etching by-product remover, a post-etch process by-product remover, an ashing process by-product remover, a cleaning composition, a photoresist (PR) remover, an etching composition for a packaging process, a cleaning agent for a packaging process, a wafer adhesive remover, an etchant, a post-etch residue stripper, an ash residue cleaner, a PR residue stripper, or a post-CMP cleaner.

As used herein, the term “residue” refers to a material including at least one of the “surface residue” and the “etching controller-derived residue”.

As used herein, the term “surface residue” refers to by-products generated during deposition and/or patterning of the metal-containing layer. In the case where the surface residue remains on a metal-containing layer pattern formed after contact with the composition, the surface residue may cause an increase in electrical resistance and/or electrical short circuits between wirings. The surface residue may be an etching residue generated as a result of the etching process, and may include, for example, an etching gas-derived residue, an organic material-derived residue, a metal-containing residue or any combination thereof.

The etching gas-derived residue may be a residue derived from an etching gas used for dry etching. The etching gas may be, for example, fluorocarbon gas. For example, the etching gas may include CHF₃, C₂F₆, CF₄, C₄F₈, C₂HF₅, or the like. The etching gas-derived residue may include the etching gas itself and/or reaction product from reactions of the etching gas with materials in contact therewith during the etching process.

The organic material-derived residue may be an organic polymer or an organic-inorganic complex derived from various organic materials included in a photoresist, a dielectric layer, a buffer layer, a diffusion barrier layer, and the like used during manufacturing and/or patterning processes of the metal-containing layer. For example, the organic material-derived residue may be a polymer including carbon, silicon, fluorine, or any combination thereof.

The metal-containing residue may be any residue including a metal separated from the metal-containing layer during manufacturing and/or patterning processes of the metal-containing layer.

As used herein, the expression “etching controller-derived residue” refers to, for example, an aggregate including the etching controller, as a material insoluble in water due to high molecular weight thereof and remaining on the surface of the metal-containing layer even after rinsing and/or drying processes following the contact between the composition and the metal-containing layer. In the case where the etching controller-derived residue remains on the metal-containing layer pattern, the etching controller-derived residue may cause an increase in electrical resistance and/or electrical short circuits between wirings.

### Method of Treating Metal-Containing Layer and Method of Manufacturing Electronic Device

A metal-containing layer including the first region and the second region, wherein the material included in the first region is different from the material included in the second region, may be more effectively treated by using the composition described above.

Therefore, a method of treating the metal-containing layer is provided, the method including preparing a substrate on which the metal-containing layer including the first region and the second region is provided, and bringing the metal-containing layer into contact with the composition. The metal-containing layer, the first region, and the second region are as described in the specification.

According to an embodiment, the first region and the second region may each independently include titanium (Ti), indium (In), aluminum (Al), lanthanum (La), scandium (Sc), gallium (Ga), copper (Cu), cobalt (Co), tungsten (W), ruthenium (Ru), molybdenum (Mo), zinc (Zn), hafnium (Hf), or any combination thereof.

According to an embodiment, the first region may include copper (Cu), cobalt (Co), tungsten (W), ruthenium (Ru), or any combination thereof.

According to another embodiment, the second region may include titanium (Ti), indium (In), aluminum (Al), lanthanum (La), scandium (Sc), gallium (Ga), or any combination thereof.

According to another embodiment, the first region may include a conductive metal (e.g., copper, cobalt, tungsten, ruthenium, or any combination thereof), and the second region may include a metal nitride, a metal oxynitride, or any combination thereof.

According to another embodiment, the second region may include titanium nitride, titanium oxynitride, or any combination thereof. Each of the titanium nitride and the titanium oxynitride may optionally further include indium (In), aluminum (Al), lanthanum (La), scandium (Sc), gallium (Ga), silicon (Si), or any combination thereof.

For example, the second region may include i) titanium nitride, ii) titanium oxynitride, iii) titanium nitride further including indium (In), aluminum (Al), lanthanum (La), scandium (Sc), gallium (Ga), silicon (Si), or any combination thereof, iv) titanium oxynitride further including indium (In), aluminum (Al), lanthanum (La), scandium (Sc), gallium (Ga), silicon (Si), or any combination thereof, or v) any combination thereof.

According to another embodiment, the first region may include copper (Cu), cobalt (Co), tungsten (W), ruthenium (Ru), or any combination thereof, and the second region may include titanium nitride, titanium oxynitride, or any combination thereof.

According to another embodiment, a second etching rate at which the composition etches the second region may be greater than a first etching rate at which the composition etches the first region. Thus, in the case where the first region and the second region of the metal-containing layer are brought into contact with the composition simultaneously, the second region may be etched faster than the first region. For example, by controlling a content ratio of compounds included in the composition, a contact time between the composition and the metal-containing layer, and the like, at least a portion of the second region or the entire second region may be etched without excessive etching (e.g., substantial etching) of the first region.

According to another embodiment, the second region of the metal-containing layer may be removed (for example, substantially removed) by the process of bringing the metal-containing layer into contact with the composition.

According to another embodiment, the surface residue is present on the metal-containing layer, and the second region of the metal-containing layer and the surface residue present thereon may be removed (for example, substantially removed) by the process of bringing the metal-containing layer into contact with the composition.

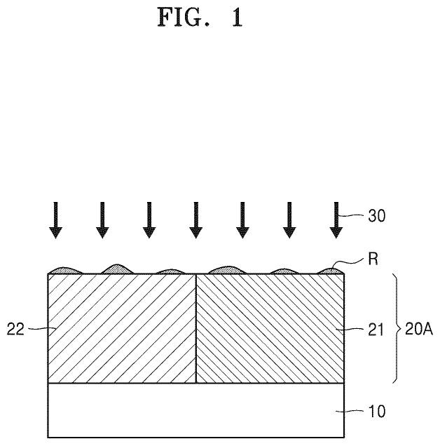

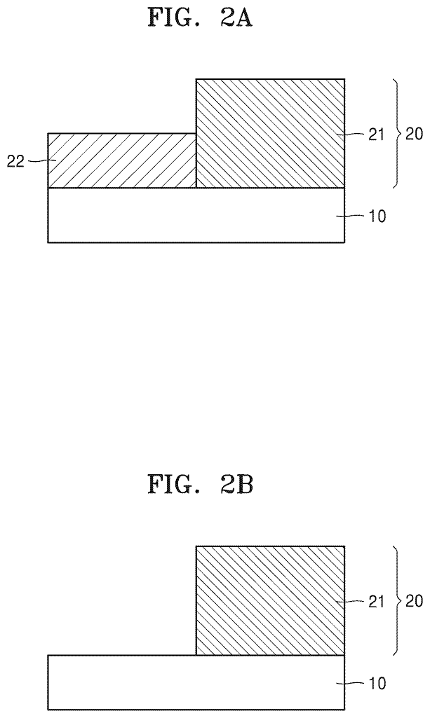

FIGS. 1, 2A, and 2B are schematic views for describing a method of treating a metal-containing layer according to an embodiment.

As illustrated in FIG. 1, a substrate 10 provided with a metal-containing layer 20A is provided. Although not shown in FIG. 1, for example, various circuit elements may be optionally disposed between the substrate 10 and the metal-containing layer 20A.

The substrate 10 may be a silicon substrate, a gallium arsenide substrate, a silicon germanium substrate, a ceramic substrate, a quartz substrate, a glass substrate for displays, a semiconductor substrate, or a semiconductor on insulator (SOI) substrate.

The metal-containing layer 20A of FIG. 1 may include a first region 21 and a second region 22. The first region 21 and the second region 22 may be arranged to be spaced apart from each other or to overlap each other at least in part, and the metal-containing layer 20A may have various patterns. The metal-containing layer 20A, the first region 21, and the second region 22 are as described in the specification.

For example, the first region 21 may include copper (Cu), cobalt (Co), tungsten (W), ruthenium (Ru), or any combination thereof, and the second region 22 may include titanium nitride, titanium oxynitride, or any combination thereof.

Surface residue R may be present on the surface of the metal-containing layer 20A of FIG. 1. The surface residue R being a by-product generated during deposition and/or patterning of the metal-containing layer 20A may be a substance that may cause an increase in electrical resistance and/or electrical short circuits between wirings in the case of remaining on a metal-containing layer pattern 20. The surface residue R is as described in the specification with reference to the “surface residue”.

The metal-containing layer 20A including the first region 21 and the second region 22 and provided with the surface residue R is brought into contact with the composition 30 as shown in FIG. 1. As a result, at least a portion of the metal-containing layer 20A may be etched and the surface residue R may be removed by the composition 30. The composition 30 includes the oxidizing agent, the ammonium-containing compound, and the etching controller as described above. Detailed description thereof is provided in the specification. The providing of the composition 30 for the contact between the metal-containing layer 20A and the composition 30 may be performed by using various methods such as dipping, coating, and spraying.

In the composition 30, i) the oxidizing agent may serve to etch at least a portion of the metal-containing layer 20A (for example, at least the second region 22) by oxidizing at least a portion of the metal in the metal-containing layer 20A to form a water-soluble complex, ii) the ammonium-containing compound may serve to maintain a high concentration of anions generated from the oxidizing agent and to effectively etch at least a portion of the metal-containing layer 20A (for example, at least the second region 22) by stabilizing the water-soluble complex generated when the anions oxidize at least a portion of the metal in the metal-containing layer 20A, and iii) the etching controller including the compound represented by Formula 1 having R₂ and R₃ as defined above may serve to selectively control the etching rate depending on the metal in the metal-containing layer 20A by selectively forming a hydrophobic protective layer without bubble formation, and at the same time, to more effectively remove the surface residue R generated during the deposition process and/or the patterning process of the metal-containing layer 20A. Therefore, the composition 30 as described above may be usefully used in various treatment processes for the metal-containing layer 20A.

According to another embodiment, upon contact with the composition 30, the surface of the first region 21 is substantially protected, and a second etching rate at which the composition 30 etches the second region 22 may be greater than a first etching rate at which the composition 30 etches the first region 21.

As a result, in the case where the first region 21 and the second region 22 of the metal-containing layer 20A are brought into contact with the composition 30 simultaneously, the second region 22 may be etched faster than the first region 21. For example, by controlling a content ratio of compounds included in the composition 30, a contact time between the composition 30 and the metal-containing layer 20A, and the like, at least a portion of the second region 22 may be etched as shown in FIG. 2A or the entire second region 22 may be etched as shown in FIG. 2B, without excessive etching (e.g., substantial etching) of the first region 21, thereby forming the metal-containing layer pattern 20 as shown in FIG. 2A or 2B.

In addition, the composition 30 including the compound represented by Formula 1 as the etching controller may effectively remove both the surface residue R generated during the deposition process and/or the patterning process of the metal-containing layer 20A and the etching controller-derived residue, without bubble formation. Therefore, the residues (that is, the surface residue R in FIG. 1 and/or the etching controller-derived residue) may not be substantially present on the surface of the metal-containing layer pattern 20 of FIGS. 2A and 2B. For example, the presence or absence of the residues (that is, the surface residue R and/or the etching controller-derived residue) on the metal-containing layer pattern 20 of FIGS. 2A and 2B may be verified by transmission electron microscope (TEM) analysis, scanning electron microscope (SEM) analysis, and the like.

Therefore, by using the composition including the oxidizing agent, the ammonium-containing compound, and the etching controller as described herein, both improved and/or excellent etching selectivity by controlling an etching rate for a certain metal and improved and/or excellent residue removal may be achieved “simultaneously”, and thus the metal-containing layer may be effectively treated at low cost.

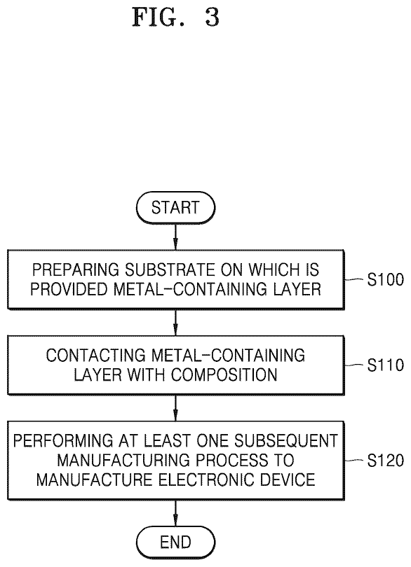

Referring to FIG. 3, a method of manufacturing an electronic device according to an embodiment may include: preparing a substrate on which is provided a metal-containing layer S100; contacting the metal-containing layer with the composition S110; and performing at least one subsequent manufacturing process to manufacture an electronic device S120.

The electronic device may be, for example, various semiconductor devices.

Therefore, according to an embodiment, the preparing of a substrate on which is provided a metal-containing layer S100 and the contacting of the metal-containing layer with the composition S110 may be used in an opening (e.g., a trench, via hole pattern etc.) formation process for forming a bitline electrode in the method of manufacturing a semiconductor device.

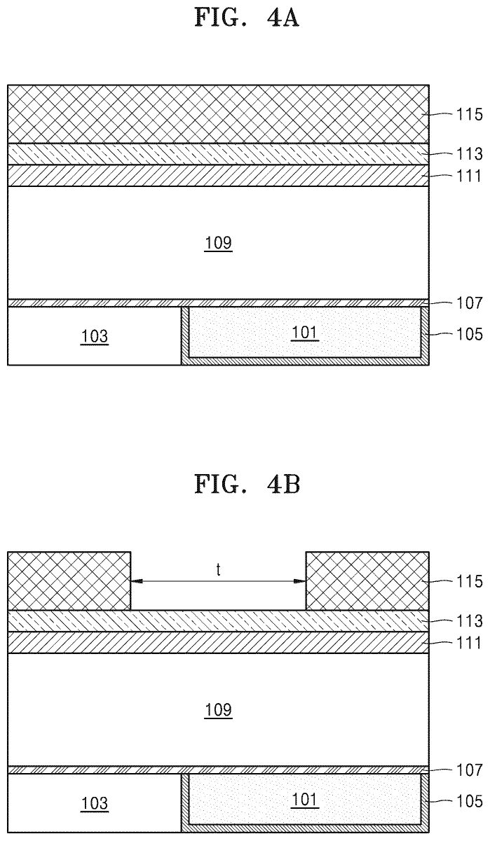

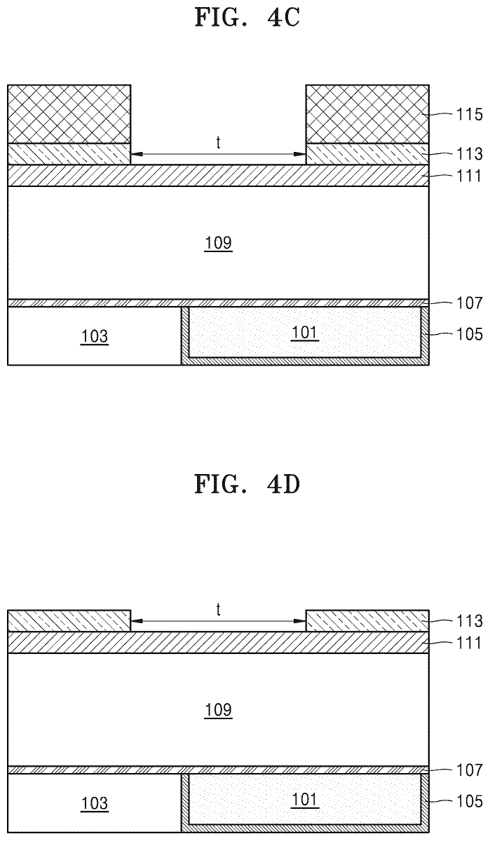

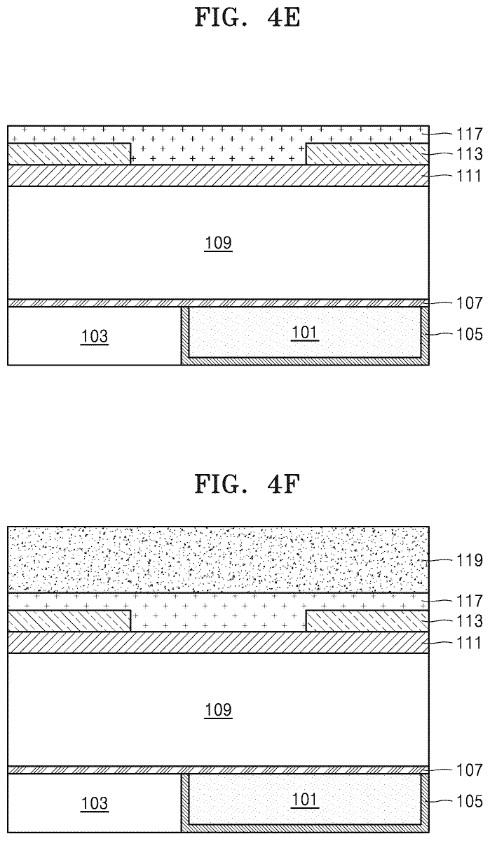

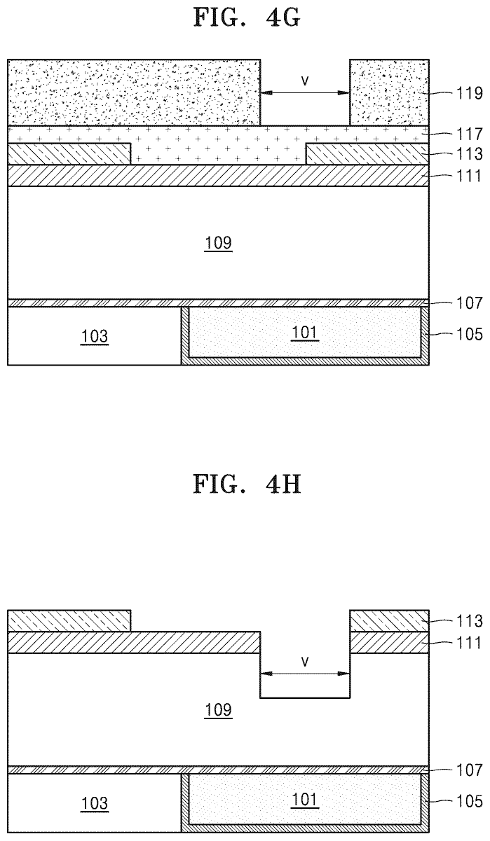

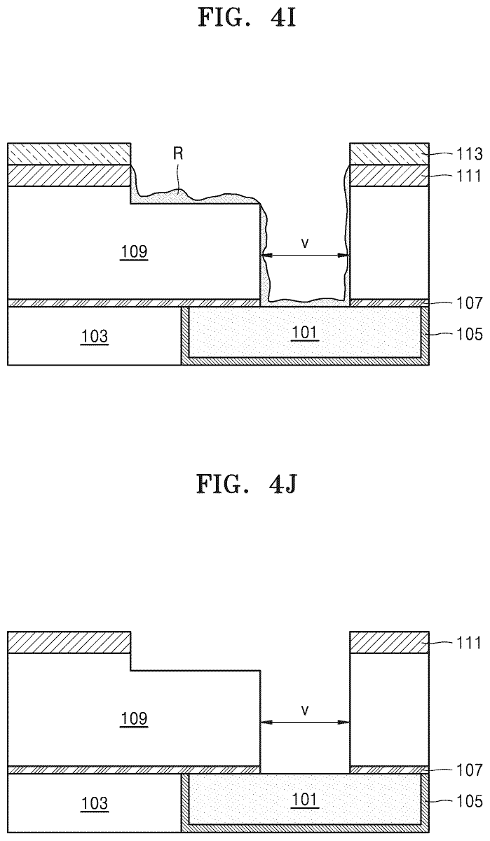

Hereinafter, with reference to FIGS. 4A to 4J, an embodiment of a trench and via hole pattern formation process for forming a bitline electrode using the composition will be described.

FIG. 4A illustrates a portion of a semiconductor substrate (transistors and the like not shown) including a first dielectric layer 103 and a metal layer 101. The metal layer 101 may include, for example, at least one of Co and Cu. A first diffusion barrier layer 105 may be arranged between the first dielectric layer 103 and the metal layer 101. The first diffusion barrier layer 105 may include, for example, tantalum, Ti, W, tantalum nitride, TiN, tungsten nitride, or any combination thereof.

A second diffusion barrier layer 107 may be arranged on the first dielectric layer 103 and the metal layer 101 of FIG. 4A. The second diffusion barrier layer 107 may include, for example, silicon nitride or nitrogen-doped silicon carbide.

A second dielectric layer 109 may be arranged on the second diffusion barrier layer 107 of FIG. 4A. The second dielectric layer 109 may include, for example, an ultra-low K (ULK) dielectric.

On the second dielectric layer 109 of FIG. 4A, a mechanically robust buffer layer 111 may be arranged to limit and/or prevent damage to the second dielectric layer 109 when depositing a hard mask layer 113. The buffer layer 111 may include, for example, tetraethyl orthosilicate (TEOS), carbon-doped silicon oxide (SiCOH), and the like.

A hard mask layer 113 may be arranged on the buffer layer 111 of FIG. 4A. The hard mask layer 113 may include i) titanium nitride (TiN), ii) titanium nitride further including In, Al, La, Sc, Ga, Zn, Hf, or any combination thereof (for example, TiAlN), or iii) any combination thereof. For example, the hard mask layer 113 may include titanium nitride.

A first photoresist 115 may be arranged on the hard mask layer 113 of FIG. 4A.

Next, the first photoresist 115 may be patterned to form a first photoresist 115 pattern having a first opening having a width t as illustrated in FIG. 4B. Then, the hard mask layer 113 may be etched according to the first photoresist 115 pattern to open a portion of the buffer layer 111 as illustrated in FIG. 4C, and then, as illustrated in FIG. 4D, the first photoresist 115 pattern may be removed using, for example, ashing to form an exposed hard mask layer 113 pattern.

Next, as illustrated in FIG. 4E, a filler layer 117 may be formed to cover the hard mask layer 113 pattern, thereby filling the opening of the hard mask layer 113 pattern. The filler layer 117 may include, for example, hydrogen silsesquioxane (HSQ) or methyl silsesquioxane (MSQ).

Thereafter, as illustrated in FIG. 4F, a second photoresist 119 may be formed on the filler layer 117, and then, the second photoresist 119 may be patterned to form a second photoresist 119 pattern having a second opening having a width v, as illustrated in FIG. 4G. Then, for example, using a reactive ion etching (RIE) and the like, the filler layer 117, a portion of the hard mask layer 113 pattern, a portion of the buffer layer 111, and a portion of the second dielectric layer 109, which are arranged under the second photoresist 119 pattern, may be etched to partially form a via hole, as illustrated in FIG. 4H, and then, the second photoresist 119 pattern and the filler layer 117 may be removed.

Next, as illustrated in FIG. 4I, according to the hard mask layer 113 pattern, the buffer layer 111, the second dielectric layer 109, and the second diffusion barrier layer 107 may be etched by using, for example, a dry etching process until the via hole reaches the metal layer 101, thereby forming a trench and via hole pattern. The etching gas used in the dry etching process may be, for example, a fluorocarbon gas (for example, CHF₃, C₂F₆, CF₄, C₄F₈, C₂HF₅, and the like).

As a result of the dry etching, a large amount of the surface residue R may exist on the inner wall of the trench and via hole pattern, as illustrated in FIG. 4I. The surface residue R may include an etching gas-derived residue, an organic material-derived residue, a metal-containing residue, or any combination thereof. The etching gas-derived residue may include the etching gas itself and/or a reaction product with any material (for example, materials included in the buffer layer 111, the second dielectric layer 109, and the like) that came into contact with the etching gas during an etching process using the etching gas. The organic material-derived residue may be a polymer derived from various organic substances included in the second photoresist 119, the second dielectric layer 109, the buffer layer 111, the second diffusion barrier layer 107, and the like. For example, the organic material-derived residue may be a polymer including carbon, silicon, fluorine, or any combination thereof. The metal-containing residue may be, for example, a residue including the metal included in the hard mask layer 113 pattern.

The surface residue R in FIG. 4I should be removed because it increases the electrical resistance of the semiconductor device or causes an electrical short of the bitline electrode to be formed later. Meanwhile, to simplify the process, the surface residue R and the hard mask layer 113 pattern may be simultaneously removed. In addition, the metal layer 101 should substantially be undamaged when the surface residue R and hard mask layer 113 pattern are removed.

To this end, by contacting the composition including an oxidizing agent, an ammonium-containing compound, and an etching controller as described above with the substrate of FIG. 4I, the substrate including a metal-containing layer including a hard mask layer 113 pattern and a metal layer 101, i) the surface residue R generated on the inner wall of the trench and via hole pattern may be removed, ii) the hard mask layer 113 pattern may be removed, and iii) the metal layer 101 may be substantially not damaged, thereby manufacturing the substrate of FIG. 4J. Without being limited by any particular theory, for example, the hard mask layer 113 pattern may be removed by an oxidizing agent and an ammonium-containing compound, the surface residue R may be removed by the etching controller, and at the same time, the metal layer 101 may be substantially not etched. Thereafter, a metallic material and the like may be filled into the trench and via hole pattern of FIG. 4J to form a bitline electrode and the like.

### Method of Manufacturing Semiconductor Device

The composition may be effectively used in a method of manufacturing a semiconductor device.

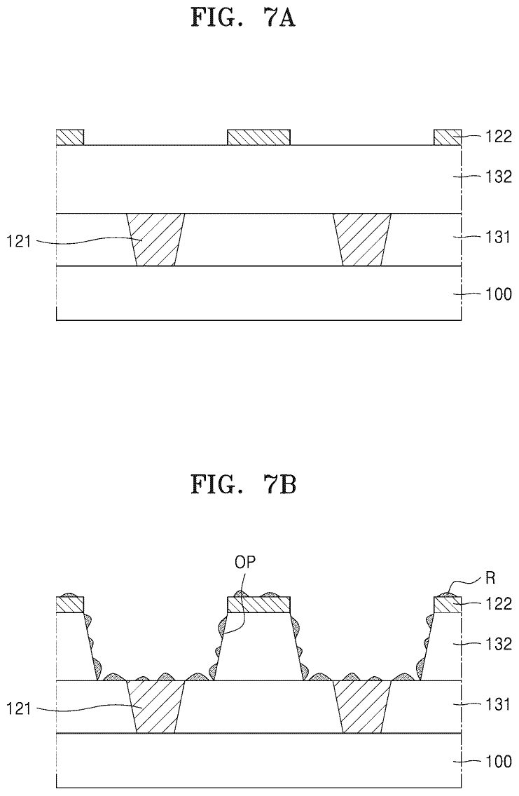

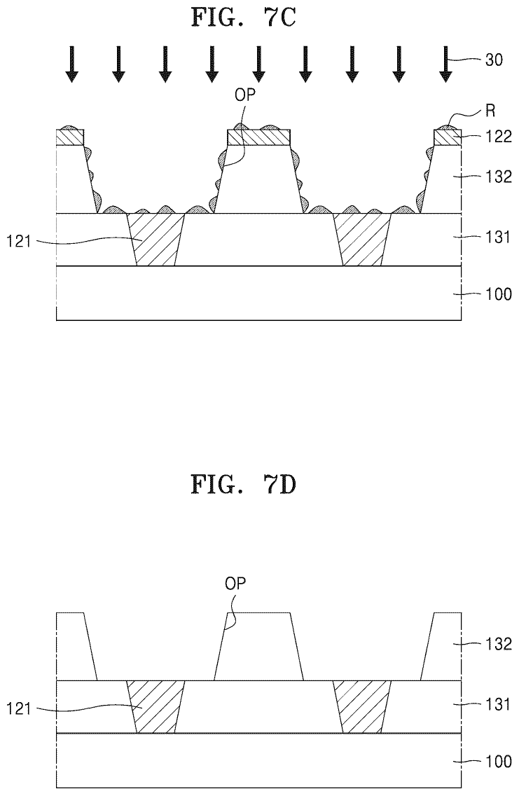

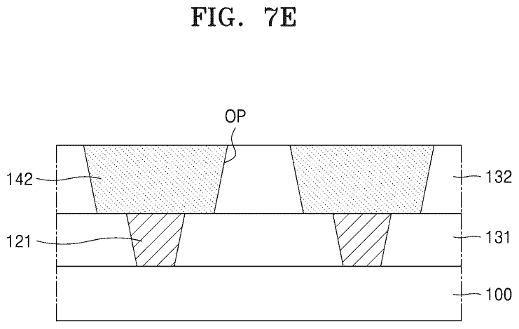

Hereinafter, a method of manufacturing a semiconductor device using the composition according to an embodiment will be described with reference to FIGS. 7A to 7E.

First, as shown in FIG. 7A, a substrate 100 provided with a first insulating layer 131, a first conductive pattern 121 arranged in the first insulating layer 131, a second insulating layer 132 disposed on the first insulating layer 131, and an opening-forming mask pattern 122 disposed on the second insulating layer 132 is prepared.

The substrate 100 is as described with reference to the substrate 10 of FIG. 1. Although not shown in FIG. 7A, the substrate 100 may include various semiconductor devices, transistors, and the like. For example, the semiconductor device may include a memory semiconductor or a non-memory semiconductor. The memory semiconductor may be i) a volatile memory such as a dynamic random access memory (DRAM) or a static random access memory (SRAM), or ii) a nonvolatile memory such as an electrically erasable programmable read-only memory (EEPROM), a flash memory (also regarded as a subset of the EEPROM), or a NAND. The non-memory semiconductor may be a microcomponent (e.g., microcontroller including processing circuitry), an analog integrated circuit (IC), a logic IC, or an optical semiconductor. The transistor may have a planar structure, a fin field-effect transistor (FinFET) structure, or a gate-all-around (GAA) structure.

Insulating materials included in each of the first insulating layer 131 and the second insulating layer 132 may include various oxides, nitrides, oxynitrides, high dielectric materials, or any combination thereof. For example, the insulating material may include silicon oxide, silicon nitride, silicon oxynitride, aluminum oxide, hafnium oxide, hafnium oxynitride, zirconium oxide, or any combination thereof. The hafnium oxide and the hafnium oxynitride may optionally further include Si, Ta, Ti, Zr, or any combination thereof. As another example, the insulating material may include tetraethyl orthosilicate (TEOS), hydrogen silsesquioxane (HSQ), methyl silsesquioxane (MSQ), and the like. The first insulating layer 131 and the second insulating layer 132 may be formed as separate layers, as shown in FIG. 7A, or may be formed as an integral layer, and various modifications may be made.

Although not illustrated in FIG. 7A, an etch stop layer may additionally be disposed between the first insulating layer 131 and the second insulating layer 132. As shown in FIG. 7B, the etch stop layer may define an etch stop line and limited and/or prevent damages to the first insulating layer 131 during an etching process for forming an opening OP in the second insulating layer 132. The etch stop layer may include aluminum oxide, silicon nitride, silicon oxynitride, silicon carbon nitride, or any combination thereof.

For the material included in the first conductive pattern 121, see the material included in the first region of the metal-containing layer in the specification. For the material included in the opening-forming mask pattern 122, see the material included in the second region of the metal-containing layer in the specification. The first conductive pattern 121 may be, for example, wiring, via, or the like.

According to an embodiment, the first conductive pattern 121 may include copper (Cu), cobalt (Co), tungsten (W), ruthenium (Ru), or any combination thereof.

According to another embodiment, the opening-forming mask pattern 122 may include titanium (Ti), indium (In), aluminum (Al), lanthanum (La), scandium (Sc), gallium (Ga), or any combination thereof.

According to another embodiment, the opening-forming mask pattern 122 may include a metal nitride, a metal oxynitride, or any combination thereof.

According to another embodiment, the opening-forming mask pattern 122 may include titanium nitride, titanium oxynitride, or any combination thereof. Each of the titanium nitride and titanium oxynitride may optionally further include indium (In), aluminum (Al), lanthanum (La), scandium (Sc), gallium (Ga), silicon (Si), or any combination thereof. For example, the opening-forming mask pattern 122 may include i) titanium nitride, ii) titanium oxynitride, iii) titanium nitride further including indium (In), aluminum (Al), lanthanum (La), scandium (Sc), gallium (Ga), silicon (Si), or any combination thereof, iv) titanium oxynitride further including indium (In), aluminum (Al), lanthanum (La), scandium (Sc), gallium (Ga), silicon (Si), or any combination thereof, or v) any combination thereof.

According to another embodiment, the first conductive pattern 121 may include copper (Cu), cobalt (Co), tungsten (W), ruthenium (Ru), or any combination thereof, and the opening-forming mask pattern 122 may include titanium nitride, titanium oxynitride, or any combination thereof.

Subsequently, as shown in FIG. 7B, the second insulating layer 132 is etched using the opening-forming mask pattern 122 to form an opening OP in the second insulating layer 132. In other words, the second insulating layer 132 may be etched along the opening-forming mask pattern 122 or through open areas of the opening-forming mask pattern 122 to forming the opening OP in the second insulating layer 132. As shown in FIG. 7B, inner walls of the opening OP may be defined by the surface of the first conductive pattern 121 and the surface of the second insulating layer 132. The etching process may be, for example, a dry etching process using an etching gas. The etching gas may be, for example, fluorocarbon gas. For example, the etching gas may include a hydrofluorocarbon, such as CHF₃, C₂F₆, CF₄, C₄F₈, C₂HF₅, and the like. In this case, as shown in FIG. 7B, the surface residue R may be formed on the surface of the opening-forming mask pattern 122 and/or in the opening OP where the surface of the first conductive pattern 121 is exposed. The surface residue R is as described in the specification. The opening OP may be, for example, trench, hole, or the like.

Subsequently, as shown in FIG. 7C, the opening-forming mask pattern 122 and the inside of the opening OP (e.g., an exposed surface of the inside of the opening OP) are brought into contact with the composition 30. The composition 30 may include the oxidizing agent, the ammonium-containing compound, and the etching controller as described above and detailed description thereof is provided in the specification.

In the composition 30, i) the oxidizing agent may serve to etch and remove the opening-forming mask pattern 122 by oxidizing a metal (e.g., titanium) in the opening-forming mask pattern 122 to form a water-soluble complex, ii) the ammonium-containing compound may serve to maintain a high concentration of anions generated from the oxidizing agent and to effectively etch and remove the opening-forming mask pattern 122 by stabilizing the water-soluble complex generated when the anions oxidize a metal (e.g., titanium) in the opening-forming mask pattern 122, and iii) the etching controller including the compound represented by Formula 1 having R₂ and R₃ as defined above may serve to selectively control the etching rate by forming a hydrophobic protective layer on the first conductive pattern 121 to suppress excessive etching (e.g., substantial etching) of the first conductive pattern 121, without bubble formation, and at the same time, to effectively remove the surface residue R generated on the inside of the opening OP during the forming the opening OP.

For example, in the case where the opening-forming mask pattern 122 and the inside of the opening OP are brought into contact with the composition 30, the surface of the first conductive pattern 121 may be substantially protected, and thus a second etching rate at which the composition 30 etches the opening-forming mask pattern 122 may be greater than a first etching rate at which the composition 30 etches the first conductive pattern 121, thereby etching and removing the opening-forming mask pattern 122 without excessive etching (e.g., substantial etching) of the first conductive pattern 121 as shown in FIG. 7D.

In addition, the composition 30 including the compound represented by Formula 1 may effectively remove both the surface residue R and the etching controller-derived residue, without bubble formation. Therefore, the residues (that is, the surface residue R in FIG. 7C and/or the etching controller-derived residue) may not be substantially present on the inside the opening OP and a surface of the second insulating layer 132 in FIG. 7D. For example, the presence or absence of the residues may be verified by transmission electron microscope (TEM) analysis, scanning electron microscope (SEM) analysis, and the like.

Therefore, by using the composition including the oxidizing agent, the ammonium-containing compound, and the etching controller as described herein, both selective etching for the opening-forming mask pattern 122 without substantially etching the surface of the first conductive pattern 121 and effective removal of the residues from the inside of the opening OP may be achieved “simultaneously”, and thus the opening OP may be effectively patterned at low cost.

Subsequently, a conductive material is introduced into the opening OP with being configured to be electrically connected to the first conductive pattern 141 to form a second conductive pattern 142 in contact with the second insulating layer 132 and electrically connected to the first conductive pattern 121 as shown in FIG. 7E. The second conductive pattern 142 may be, for example, wiring, via, or the like.

The conductive material and the second conductive pattern 142 may include copper (Cu), carbon (C), silver (Ag), cobalt (Co), tantalum (Ta), indium (In), tin (Sn), zinc (Zn), manganese (Mn), titanium (Ti), magnesium (Mg), chromium (Cr), germanium (Ge), strontium (Sr), platinum (Pt), aluminum (Al), zirconium (Zr), tungsten (W), ruthenium (Ru), iridium (Ir), rhodium (Rh), or any combination thereof. Meanwhile, the conductive material and the second conductive pattern 142 may optionally further include titanium (Ti), titanium nitride (TiN), tantalum (Ta), tantalum nitride (TaN), tantalum carbonitride (TaCN), tungsten (W), tungsten nitride (WN), tungsten carbonitride (WCN), zirconium (Zr), zirconium nitride (ZrN), vanadium (V), vanadium nitride (VN), niobium (Nb), niobium nitride (NbN), or any combination thereof. The second conductive pattern 142 may be formed by using various methods such as atomic layer deposition (ALD) and chemical vapor deposition (CVD).

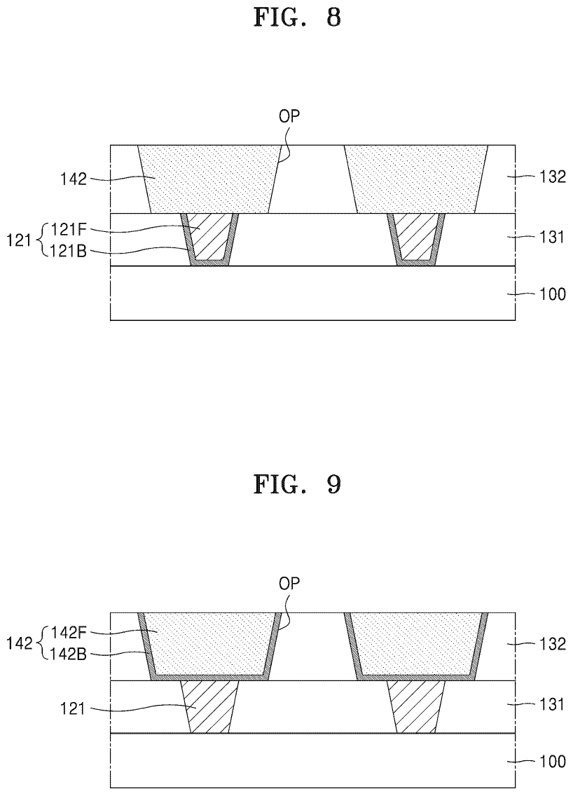

FIG. 8 schematically shows a semiconductor device according to another embodiment, which is the same as the semiconductor device illustrated in FIG. 7E, except that the first conductive pattern 121 includes a first barrier layer pattern 121B and a first filling layer 121F disposed on the first barrier layer pattern 121B. The first barrier layer pattern 121B and the first filling layer 121F may include different materials. For example, the first barrier layer pattern 121B may include cobalt, and the first filling layer 121F may include copper, without being limited thereto. A method of manufacturing a semiconductor device of FIG. 8 may be understood with reference to the description of the method of manufacturing a semiconductor device shown in FIG. 7E, except that the first barrier layer pattern 121B is formed, and then the first filling layer 121F is formed on the first barrier layer pattern 121B during formation of the first conductive pattern 121.

FIG. 9 schematically shows a semiconductor device according to another embodiment, which is the same as the semiconductor device illustrated in FIG. 7E, except that the second conductive pattern 142 includes a second barrier layer pattern 142B and a second filling layer 142F disposed on the second barrier layer pattern 142B. The second barrier layer pattern 142B and the second filling layer 142F may include different materials. For example, the second barrier layer pattern 142B may include cobalt (Co), titanium (Ti), titanium nitride (TiN), tantalum (Ta), tantalum nitride (TaN), tantalum carbonitride (TaCN), tungsten (W), tungsten nitride (WN), tungsten carbonitride (WCN), zirconium (Zr), zirconium nitride (ZrN), vanadium (V), vanadium nitride (VN), niobium (Nb), niobium nitride (NbN), or any combination thereof. The second filling layer 142F may include copper (Cu), carbon (C), silver (Ag), cobalt (Co), tantalum (Ta), indium (In), tin (Sn), zinc (Zn), manganese (Mn), titanium (Ti), magnesium (Mg), chromium (Cr), germanium (Ge), strontium (Sr), platinum (Pt), aluminum (Al), zirconium (Zr), tungsten (W), ruthenium (Ru), iridium (Ir), rhodium (Rh), or any combination thereof. As another example, the second barrier layer pattern 142B may include a combination of cobalt and tantalum nitride, a combination of cobalt and titanium nitride, or cobalt, and the second filling layer 142F may include copper, without being limited thereto. A method of manufacturing the semiconductor device of FIG. 9 may be understood with reference to the description of the method of manufacturing a semiconductor device shown in FIG. 7E, except that the second barrier layer pattern 142B is formed, and then the second filling layer 142F is formed on the second barrier layer pattern 142B during formation of the second conductive pattern 142.

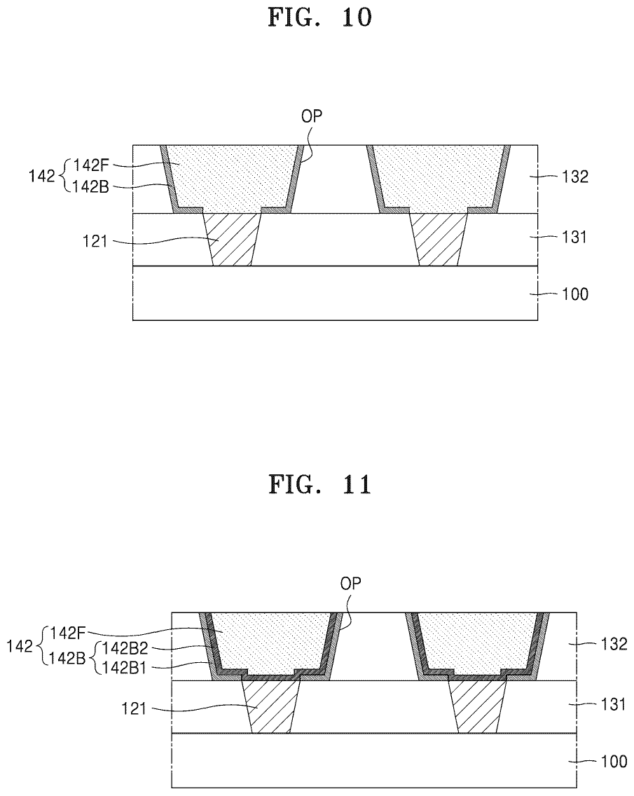

FIG. 10 schematically shows a semiconductor device according to another embodiment, which is the same as the semiconductor device illustrated in FIG. 9, except that the second barrier layer pattern 142B has an opening corresponding to the surface of the first conductive pattern 121. A method of manufacturing the semiconductor device of FIG. 10 may be understood with reference to the description of the method of manufacturing a semiconductor device shown in FIG. 9, except that a process of forming the opening corresponding to the surface of the first conductive pattern 121 is added during formation of the second barrier layer pattern 142B.

FIG. 11 schematically shows a semiconductor device according to another embodiment, which is the same as the semiconductor device illustrated in FIG. 9, except that the second barrier layer pattern 142B includes a first layer 142B1 having an opening corresponding to the surface of the first conductive pattern 121 and a second layer 142B2 disposed on the first layer 142B1 and covering the first conductive pattern 121. For example, the first layer 142B1 may include titanium nitride, tantalum nitride, or any combination thereof, and the second layer 142B2 may include cobalt (Co). A method of manufacturing the semiconductor device of FIG. 11 may be understood with reference to the description of the method of manufacturing a semiconductor device shown in FIG. 9, except that the first layer 142B1 having the opening corresponding to the surface of the first conductive pattern 121 is formed, and then the second layer 142B2 is formed.

### Examples 1 to 5 and Comparative Examples C1 to C6

25 wt % of hydrogen peroxide, 0.5 wt % of (NH₄)₂HPO₄, etching controller, and tetramethylammonium hydroxide (TMAH) weighed in an amount selected within a range of 0.01 wt % to 0.5 wt % were mixed to prepare compositions of Examples 1 to 5 and Comparative Examples C₁ to C₆. As etching controllers in the compositions, the materials and the amounts listed in Table 1 were used. An amount of TMAH in each composition was selected to adjust the pH of each composition to 7.5, and the remainder of the composition corresponds to water (deionized water).

### Comparative Example C7

A composition was prepared in the same manner as Example 1, except that the etching controller was not used.

### Evaluation Example 1

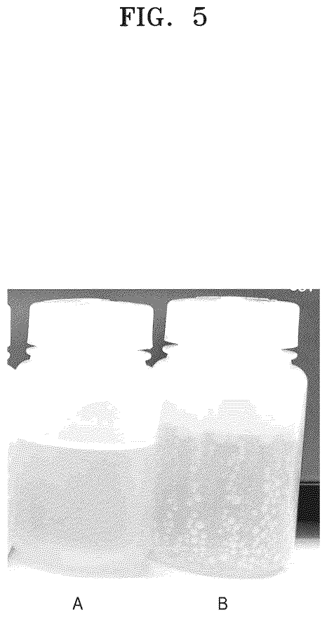

After each of the compositions of Examples 1 to 5 and Comparative Examples C₁ to C₇ was manufactured, bubble formation was visually evaluated, and the results are summarized in Table 1. FIG. 5 is a photograph, in which A shows the composition of Example 1, and B shows the composition of Comparative Example C1.

TABLE 1

| | | Ammonium- | | | |
|---|---|---|---|---|---|
| | Oxidizing | containing | | | Bubble |
| Classification | agent | compound | Etching controller | | formation |
| Example 1 | Hydrogen | (NH₄)₂HPO₄ | 1 | | N |
| | peroxide | (0.5 wt %) | (0.2 wt %) | | |
| | (25 wt %) | | | | |
| Example 2 | Hydrogen | (NH₄)₂HPO₄ | 2 | | N |
| | peroxide | (0.5 wt %) | (0.2 wt %) | | |
| | (25 wt %) | | | | |
| Example 3 | Hydrogen | (NH₄)₂HPO₄ | 1 | C11 | N |
| | peroxide | (0.5 wt %) | (0.13 wt %) | (0.07 wt %) | |
| | (25 wt %) | | | | |
| Example 4 | Hydrogen | (NH₄)₂HPO₄ | 1 | C11 | N |
| | peroxide | (0.5 wt %) | (0.18 wt %) | (0.02 wt %) | |
| | (25 wt %) | | | | |
| Example 5 | Hydrogen | (NH₄)₂HPO₄ | 1 | C5 | N |
| | peroxide | (0.5 wt %) | (0.1 wt %) | (0.1 wt %) | |
| | (25 wt %) | | | | |

| | | | | |
|---|---|---|---|---|
| Comparative | Hydrogen | (NH₄)₂HPO₄ | C1 | Y |
| Example C1 | peroxide | (0.5 wt %) | (0.2 wt %) | |
| | (25 wt %) | | | |
| Comparative | Hydrogen | (NH₄)₂HPO₄ | C2 | N |
| Example C2 | peroxide | (0.5 wt %) | (0.2 wt %) | |
| | (25 wt %) | | | |
| Comparative | Hydrogen | (NH₄)₂HPO₄ | C3 | Y |
| Example C3 | peroxide | (0.5 wt %) | (0.2 wt %) | |
| | (25 wt %) | | | |
| Comparative | Hydrogen | (NH₄)₂HPO₄ | C4 | N |
| Example C4 | peroxide | (0.5 wt %) | (0.2 wt %) | |
| | (25 wt %) | | | |
| Comparative | Hydrogen | (NH₄)₂HPO₄ | C5 | N |
| Example C5 | peroxide | (0.5 wt %) | (0.2 wt %) | |
| | (25 wt %) | | | |
| Comparative | Hydrogen | (NH₄)₂HPO₄ | C6 | Y |
| Example C6 | peroxide | (0.5 wt %) | (0.2 wt %) | |
| | (25 wt %) | | | |
| Comparative | Hydrogen | (NH₄)₂HPO₄ | — | N |
| Example C7 | peroxide | (0.5 wt %) | | |
| | (25 wt %) | | | |

“N” for bubble formation: No bubbles observed.
“Y” for bubble formation: Bubbles observed.

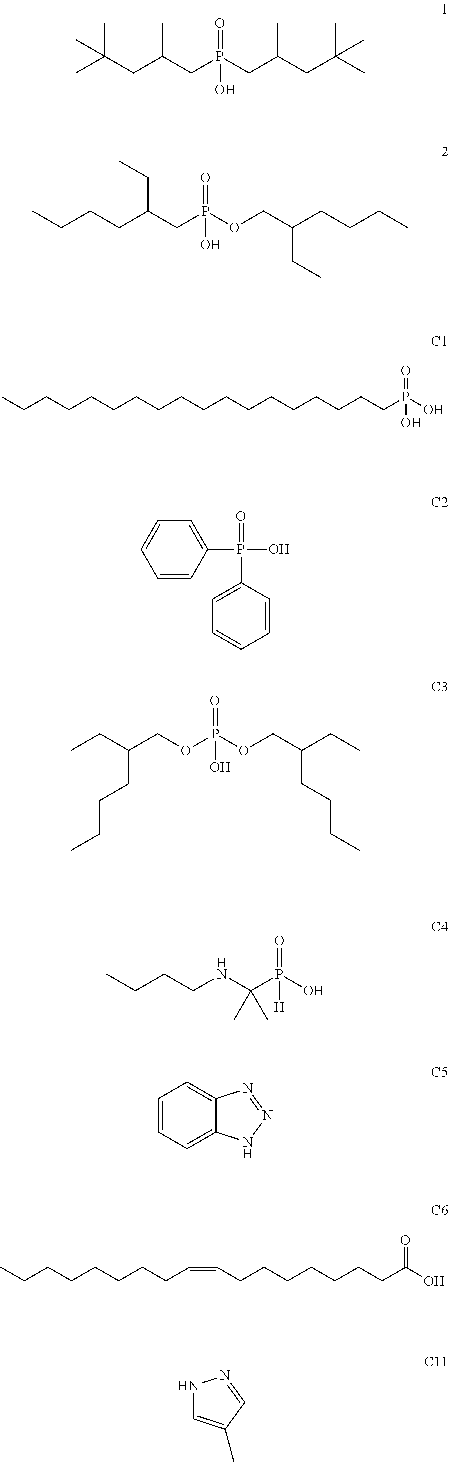

From FIG. 5, it can be confirmed that bubble formation was not observed in the composition of Example 1, but bubble formation was observed in the composition of Comparative Example C1. Similarly, in the composition of Examples 2 to 5, bubble formation was not observed as in the composition of Example 1, and in the compositions of Comparative Examples C₃ and C₆, bubble formation was observed as in the composition of Comparative Example C1.

From FIG. 5 and Table 1, it was confirmed that the compositions of Comparative Examples C₁, C₃, and C₆ were unsuitable for use in the treatment of a metal-containing layer because bubble formation was observed after the compositions were manufactured. Therefore, the remaining compositions, that is, the compositions of Examples 1 to 5 and Comparative Examples C₂, C₄, C₅, and C₇, were used to perform the following Evaluation Example 2.

### Evaluation Example 2

As shown in FIG. 7B, a substrate including a first conductive pattern arranged in the first insulating layer, an opening formed in the second insulating layer, and an opening-forming mask pattern disposed on the second insulating layer was prepared. In the substrate, the first insulating layer and the second insulating layer were formed by using silicon oxide, the opening-forming mask pattern was formed by using titanium nitride, the first conductive pattern was formed by using copper, and CHF₃ etching gas was used to form the opening. Subsequently, the substrate was immersed in a dip type bath containing the composition of Example 1 at 25° C. for 5 minutes, and rinsing and drying processes were performed. Then, the presence or absence of the residues in the opening was observed by using a scanning electron microscope (SEM) to evaluate residue removal performance of the composition of Example 1, and the results are shown in Table 2. Additionally, the pH of the composition of Example 1 was evaluated using a PH meter, and the results are summarized in Table 2.

Thereafter, the composition of Example 1 was placed in each of two beakers and heated to 50° C., and a copper film and a cobalt film, which were subjected to dipping in a mixture of HF and water with a volume ratio of 1:200 for 40 seconds at room temperature, were immersed in the respective beakers for 10 minutes and 5 minutes. Then, the thicknesses of the copper film and the cobalt film were measured by using X-ray fluorescence spectrometry (XRF) (S8 Tiger, BRUKER) to evaluate the rate at which the composition of Example 1 etches the copper film (Å/min), and the rate at which the composition of Example 1 etches the cobalt film (Å/min). The results are summarized in Table 2.

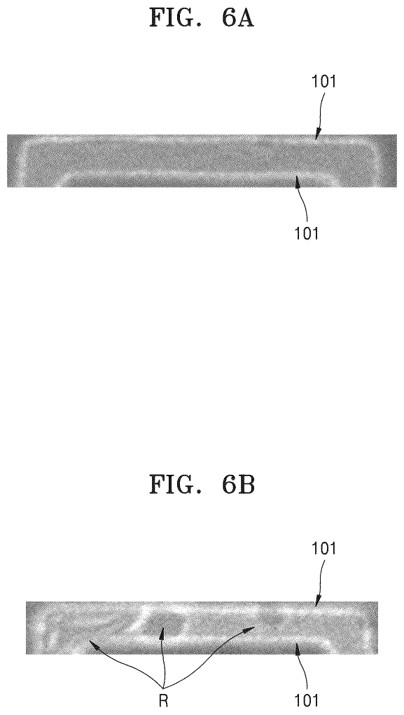

The tests were repeated using each of the compositions of Examples 2 to 5 and Comparative Examples C2, C4, C5, and C7, and the results are summarized in Table 2. FIG. 6A is an SEM image of the inside of the opening observed after performing the rinsing and drying process using Example 1, and FIG. 6B is an SEM image of the inside of the opening observed after performing the rinsing and drying process using Comparative Example C2. In FIGS. 6A and 6B, the first conductive pattern is indicated by reference number “101.”

TABLE 2

| | | | | | | | Etching | Etching |
|---|---|---|---|---|---|---|---|---|
| | | Ammonium- | | | | | rate for | rate for |
| | Oxidizing | containing | Etching | | | Residue | Cu film | Co film |
| Classification | agent | compound | controller | | pH | removal | (Å/min) | (Å/min) |
| Example | Hydrogen | (NH₄)₂HPO₄ | 1 | | 7.5 | Good | 0.4 | 1.2 |
| 1 | peroxide | (0.5 wt %) | (0.2 wt %) | | | | | |
| | (25 wt %) | | | | | | | |
| Example | Hydrogen | (NH₄)₂HPO₄ | 2 | | 7.5 | Good | 0.8 | 3.2 |
| 2 | peroxide | (0.5 wt %) | (0.2 wt %) | | | | | |
| | (25 wt %) | | | | | | | |
| Example | Hydrogen | (NH₄)₂HPO₄ | 1 | C11 | 7.5 | Good | <0.1 | 0.2 |
| 3 | peroxide | (0.5 wt %) | (0.13 | (0.07 | | | | |
| | (25 wt %) | | wt %) | wt %) | | | | |
| Example | Hydrogen | (NH₄)₂HPO₄ | 1 | C11 | 7.5 | Good | <0.1 | 0.5 |
| 4 | peroxide | (0.5 wt %) | (0.18 | (0.02 | | | | |
| | (25 wt %) | | wt %) | wt %) | | | | |
| Example | Hydrogen | (NH₄)₂HPO₄ | 1 | C5 | 7.5 | Good | 1.6 | 0.1 |
| 5 | peroxide | (0.5 wt %) | (0.1 | (0.1 | | | | |
| | (25 wt %) | | wt %) | wt %) | | | | |
| Comparative | Hydrogen | (NH₄)₂HPO₄ | C2 | | 7.5 | Poor | 0.9 | 11.4 |
| Example | peroxide | (0.5 wt %) | (0.2 wt %) | | | | | |
| C2 | (25 wt %) | | | | | | | |
| Comparative | Hydrogen | (NH₄)₂HPO₄ | C4 | | 7.5 | Poor | 0.2 | 11.1 |
| Example | peroxide | (0.5 wt %) | (0.2 wt %) | | | | | |
| C4 | (25 wt %) | | | | | | | |
| Comparative | Hydrogen | (NH₄)₂HPO₄ | C5 | | 7.5 | Poor | 2.6 | 0.2 |
| Example | peroxide | (0.5 wt %) | (0.2 wt %) | | | | | |
| C5 | (25 wt %) | | | | | | | |
| Comparative | Hydrogen | (NH₄)₂HPO₄ | — | | 7.5 | Poor | 1.4 | >10 |
| Example | peroxide | (0.5 wt %) | | | | | | |
| C7 | (25 wt %) | | | | | | | |

“Good” residue removal: No residue of 10 nm or more in length was observed.
“Poor” residue removal: Residues of 10 nm or more in length were observed.

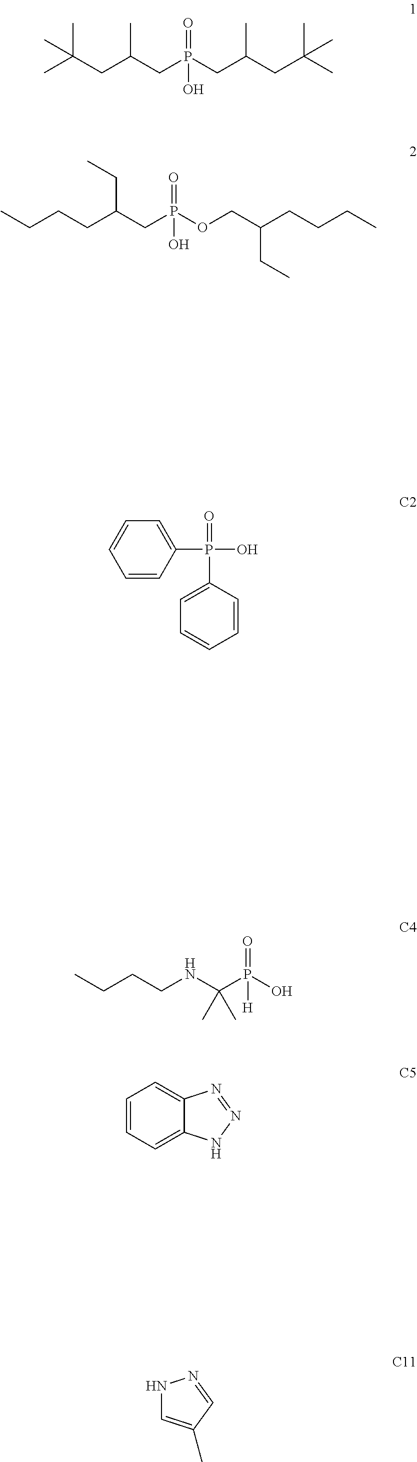

In FIG. 6A, no residue was substantially observed, but in FIG. 6B, a residue indicated as “R” was observed. From FIGS. 6A and 6B, it can be confirmed that the cleaning performance of the composition of Example 1 was good and the cleaning performance of the composition of Comparative Example C2 was poor. Similarly, no residue was observed on the inside of the opening in contact with the composition of Examples 2 to 5, as with the composition of Example 1, whereas a residue was observed on the inside of the opening in contact with each of the compositions of Comparative Examples C4, C5, and C7, as with the composition of Comparative Example C2. From FIGS. 6A and 6 B and Table 2, it can be confirmed that the compositions of Examples 1 to 5 had superior residue removal performance compared to the compositions of Comparative Examples C2, C4, C5, and C7.

In addition, from Table 2, it can be confirmed that i) the compositions of Examples 1 to 4 had superior copper film etching inhibition performance compared to the compositions of Comparative Examples C2, C5, and C7, and ii) the compositions of Examples 1 to 5 had superior cobalt film etching inhibition performance compared to the compositions of Comparative Examples C2, C4, and C7.

From FIGS. 6A and 6B and Table 2, it can be confirmed that the compositions of Examples 1 to 5 had superior cleaning performance for residues generated during a deposition process and/or a patterning process of a metal-containing layer, compared to the compositions of Comparative Examples C2, C4, C5 and C7, and at the same time, was capable of more effectively inhibiting etching of the copper film and the cobalt film.

The composition has improved and/or excellent etching rate control performance and improved and/or excellent cleaning performance without bubble formation, and thus, may be effectively used in various treatment processes for various metal-containing layers, such as etching and cleaning processes. Therefore, by treating a metal-containing layer using the composition, higher-quality electronic devices may be manufactured.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A method of manufacturing a semiconductor device, the method comprising:
preparing a first insulating layer, a first conductive pattern in the first insulating layer, a second insulating layer on the first insulating layer, and an opening-forming mask pattern on the second insulating layer;
forming an opening in the second insulating layer by etching the second insulating layer using the opening-forming mask pattern;
contacting the opening-forming mask pattern and an exposed surface of an inside of the opening with a composition; and
providing a conductive material in the opening, the conductive material being configured to be electrically connected to the first conductive pattern, wherein
the composition comprises an oxidizing agent, an ammonium-containing compound, and an etching controller, and
the etching controller comprises a compound represented by Formula 1, 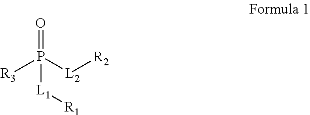
wherein, in Formula 1,
L₁ and L₂ are each independently a single bond or oxygen,
R₁ is hydrogen, a C₁-C₅₀ alkyl group, or a C₂-C₅₀ alkenyl group,
R₂ and R₃ are each independently a C₁-C₅₀ alkyl group or a C₂-C₅₀ alkenyl group, and
in R₂, R₃, and R₁ when R₁ is not hydrogen, at least one hydrogen in each of the C₁-C₅₀ alkyl group and the C₂-C₅₀ alkenyl group is optionally substituted with a halogen atom.

2. The method of claim 1,
wherein the first conductive pattern comprises copper (Cu), cobalt (Co), tungsten (W), ruthenium (Ru), or any combination thereof, and
the opening-forming mask pattern comprises titanium (Ti), indium (In), aluminum (Al), lanthanum (La), scandium (Sc), gallium (Ga), or any combination thereof.

3. The method of claim 1,
wherein the opening-forming mask pattern comprises a metal nitride, a metal oxynitride, or any combination thereof.

4. The method of claim 1,
wherein the opening-forming mask pattern comprises titanium nitride, titanium oxynitride, or any combination thereof, and
each of the titanium nitride and the titanium oxynitride optionally further comprises indium (In), aluminum (Al), lanthanum (La), scandium (Sc), gallium (Ga), silicon (Si), or any combination thereof.

5. The method of claim 1,
wherein the first conductive pattern comprises a first barrier layer pattern and a first filling layer on the first barrier layer pattern.

6. The method of claim 1, wherein
during the forming of the opening, a surface residue is formed on at least one of a surface of the opening-forming mask pattern and the exposed surface of the inside of the opening, and
the opening-forming mask pattern and the surface residue are removed by the contacting the opening-forming mask pattern and the exposed surface of the inside of the opening with the composition.

7. The method of claim 1,
wherein the ammonium-containing compound of the composition comprises dihydrogen phosphate ([H₂PO₄]⁻), hydrogen phosphate ([HPO₄]²⁻), or phosphate ([PO₄]³⁻).

8. The method of claim 1, wherein,
in Formula 1, R₂ and R₃ are each a branched C₃-C₅₀ alkyl group.

9. The method of claim 1, wherein
an amount of the etching controller is about 0.001 wt % to about 10 wt % with respect to 100 wt % of the composition.

10. A composition comprising:
an oxidizing agent;
an ammonium-containing compound; and
an etching controller, wherein
the etching controller comprises a compound represented by Formula 1: 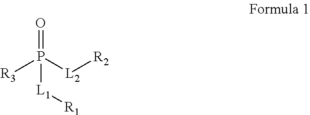
wherein, in Formula 1,
L₁ and L₂ are each independently a single bond or oxygen,
R₁ is hydrogen, a C₁-C₅₀ alkyl group, or a C₂-C₅₀ alkenyl group,
R₂ and R₃ are each independently a C₁-C₅₀ alkyl group or a C₂-C₅₀ alkenyl group, and
in R₂, R₃, and R₁ when R₁ is not hydrogen, at least one hydrogen in each of the C₁-C₅₀ alkyl group and the C₂-C₅₀ alkenyl group is optionally substituted with a halogen atom.

11. The composition of claim 10, wherein the oxidizing agent comprises hydrogen peroxide and an amount of the oxidizing agent is about 1 wt % to about 50 wt % with respect to 100 wt % of the composition.

12. The composition of claim 10,
wherein the ammonium-containing compound of the composition comprises dihydrogen phosphate ([H₂PO₄]⁻), hydrogen phosphate ([HPO₄]²⁻), or phosphate ([PO₄]³⁻).

13. The composition of claim 10, wherein
the ammonium-containing compound comprises a compound represented by Formula 11-1, a compound represented by Formula 11-2, a compound represented by Formula 11-3, or any combination thereof, 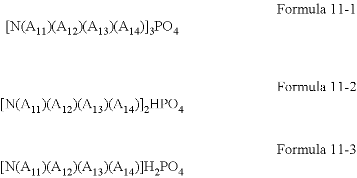
wherein, in Formulae 11-1 to 11-3, A₁₁ to A₁₄ are each independently hydrogen, a C₁-C₃₀ alkyl group, a C₂-C₃₀ alkenyl group, a C₃-C₃₀ carbocyclic group, or a C₁-C₃₀ heterocyclic group.

14. The composition of claim 10, wherein an amount of the ammonium-containing compound is about 0.01 wt % to about 10 wt % with respect to 100 wt % of the composition.

15. The composition of claim 10, wherein,
in Formula 1, R₂ and R₃ are each a branched C₃-C₅₀ alkyl group.

16. The composition of claim 10, wherein,
wherein the etching controller further comprises an azole-containing compound and the azole-containing compound comprises a pyrazole group, an imidazole group, a triazole group, or tetrazole group.

17. The composition of claim 10, wherein
an amount of the etching controller is about 0.001 wt % to about 10 wt % with respect to 100 wt % of the composition.

18. A method of treating a metal-containing layer, the method comprising:
preparing a metal-containing layer including a first region and a second region, wherein a material in the first region of the metal-containing layer is different from a material in the second region of the metal-containing layer; and
contacting the metal-containing layer with a composition,
wherein the first region of the metal-containing layer and the second region of the metal-containing layer each independently comprise titanium (Ti), indium (In), aluminum (Al), lanthanum (La), scandium (Sc), gallium (Ga), copper (Cu), cobalt (Co), tungsten (W), ruthenium (Ru), molybdenum (Mo), zinc (Zn), hafnium (Hf), or any combination thereof,
the composition comprises an oxidizing agent, an ammonium-containing compound, and an etching controller, and
the etching controller comprises a compound represented by Formula 1: 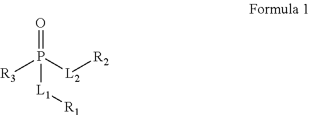
wherein, in Formula 1,
L₁ and L₂ are each independently a single bond or oxygen,
R₁ is hydrogen, a C₁-C₅₀ alkyl group, or a C₂-C₅₀ alkenyl group,
R₂ and R₃ are each independently a C₁-C₅₀ alkyl group or a C₂-C₅₀ alkenyl group, and
in R₂, R₃, and R₁ when R₁ is not hydrogen, at least one hydrogen in each of the C₁-C₅₀ alkyl group and the C₂-C₅₀ alkenyl group is optionally substituted with a halogen atom.

19. The method of claim 18, wherein
the first region of the metal-containing layer comprises copper (Cu), cobalt (Co), tungsten (W), ruthenium (Ru), or any combination thereof, and
the second region of the metal-containing layer comprises titanium (Ti), indium (In), aluminum (Al), lanthanum (La), scandium (Sc), gallium (Ga), or any combination thereof.

20. The method of claim 18, wherein
a second etching rate at which the composition etches the second region of the metal-containing layer is greater than a first etching rate at which the composition etches the first region of the metal-containing layer.
